(19) United States
(12) Patent Application Publication
(10) Pub. No.: US 2023/0212773 A1
(43) Pub. Date: Jul. 6, 2023

(54) SURFACE PRETREATMENT FOR ELECTROPLATING NANOTWINNED COPPER

(71) Applicant: Lam Research Corporation, Fremont, CA (US)

(72) Inventors: Justin OBERST, Beaverton, OR (US); Bryan L. BUCKALEW, Tualatin, OR (US); Thomas Anand PONNUSWAMY, Sherwood, OR (US); Steven T. MAYER, Aurora, OR (US); Stephen J. BANIK, II, Philadelphia, PA (US)

(21) Appl. No.: 17/998,886

(22) PCT Filed: May 12, 2021
(86) PCT No.: PCT/US2021/032072

§ 371 Date: Nov. 15, 2022

Related U.S. Application Data
(60) Provisional application No. 63/201,019, filed on Apr. 8, 2021.
(60) Provisional application No. 63/026,492, filed on May 18, 2020.

(51) Int. Cl. C25D 5/02; C25D 5/34; C25D 3/38; H01L 21/288; H01L 21/3213; H01L 21/768

(52) U.S. Cl. CPC C25D 5/02; C25D 5/34; C25D 3/38; H01L 21/2885; H01L 21/32134; H01L 21/76885; H01L 21/76877

(57) ABSTRACT

Nanotwinned copper and non-nanotwinned copper may be electroplated to form mixed crystal structures such as 2-in-1 copper via and RDL structures or 2-in-1 copper via and pillar structures. Nanotwinned copper may be electroplated on a non-nanotwinned copper layer by pretreating a surface of the non-nanotwinned copper layer with an oxidizing agent or other chemical reagent. Alternatively, nanotwinned copper may be electroplated to partially fill a recess in a dielectric layer, and non-nanotwinned copper may be electroplated over the nanotwinned copper to fill the recess. Copper overburden may be subsequently removed.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to methods and apparatuses for electroplating copper features and, more particularly, to optimizing conditions for electroplating nanotwinned copper features.

### BACKGROUND

Electrochemical deposition processes are well-established in modern integrated circuit fabrication. The transition from aluminum to copper metal line interconnections in the early years of the twenty-first century drove a need for increasingly sophisticated electrodeposition processes and plating tools. Much of the sophistication evolved in response to the need for ever smaller current carrying lines in device metallization layers. Copper lines are formed by electroplating the metal into very thin, high-aspect ratio trenches and vias in a methodology commonly referred to as “damascene” processing (pre-passivation metallization).

Electrochemical deposition is poised to fill a commercial need for sophisticated packaging and multichip interconnection technologies known generally and colloquially as wafer level packaging (WLP) and through silicon via (TSV) electrical connection technology. These technologies present their own very significant challenges due in part to the generally larger feature sizes (compared to Front End of Line (FEOL) interconnects) and high aspect ratios.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing nanotwinned copper on a plated copper feature. The method includes electroplating copper in a recessed feature of a substrate to form a plated copper feature, exposing a surface of the plated copper feature to one or more oxidizing agents or other chemical reagents to treat the plated copper feature, and electroplating nanotwinned copper on the plated copper feature. The plated copper feature includes non-nanotwinned copper.

In some implementations, the nanotwinned copper comprises a nanotwinned region having (111)-oriented nanotwinned crystal copper grains. In some implementations, the nanotwinned copper is electroplated without a transition region or with a transition region having a thickness less than about 0.5 μm, wherein the transition region is located between the nanotwinned region and the surface of the plated copper feature and without (111)-oriented nanotwinned crystal copper grains. In some implementations, the method further includes annealing the nanotwinned copper to eliminate or reduce a size of the transition region. In some implementations, electroplating the nanotwinned copper includes contacting the surface of the plated copper feature with a nanotwinned copper electroplating solution, and applying a first current to the substrate when the plated copper feature is contacted with the nanotwinned copper electroplating solution to electroplate the nanotwinned copper having a plurality of nanotwins, where the first current comprises a pulsed current waveform that alternates between a constant current and no current. In some implementations, the nanotwinned copper electroplating solution is free of accelerators. In some implementations, exposing the surface of the plated copper feature to the one or more oxidizing agents or other chemical reagents includes exposing the surface of the plated copper feature to a wet treatment solution including an aqueous solution of a peroxide, sulfuric acid, dissolved ozone, or combinations thereof. In some implementations, exposing the surface of the plated copper feature to the one or more oxidizing agents or other chemical reagents includes exposing the surface of the plated copper feature to a dry treatment including an oxygen plasma or ozone. In some implementations, exposing the surface of the plated copper feature to the one or more oxidizing agents or other chemical reagents includes exposing the surface of the plated copper feature to a wet treatment solution including one or more electroplating leveling compounds. In some implementations, exposing the surface of the plated copper feature to the one or more oxidizing agents or other chemical reagents includes exposing the surface of the plated copper feature to a thermal treatment with forming gas. In some implementations, exposing the surface of the plated copper feature to the one or more oxidizing agents or other chemical reagents includes exposing the surface of the plated copper feature to different wet treatment solutions sequentially. In some implementations, the nanotwinned copper has a thickness equal to or less than about 5 μm.

Another aspect involves a method of depositing a nanotwinned copper feature. The method includes providing a substrate having a seed layer with one or more contaminants on a surface of the seed layer, exposing the surface of the seed layer to one or more oxidizing agents or other chemical reagents to treat the seed layer, and electroplating a nanotwinned copper feature on the seed layer.

In some implementations, exposing the surface of the seed layer to the one or more oxidizing agents or other chemical reagents includes exposing the surface of the seed layer to a wet treatment solution including an aqueous solution of a peroxide, sulfuric acid, dissolved ozone, or combinations thereof. In some implementations, exposing the surface of the seed layer to the one or more oxidizing agents or other chemical reagents includes exposing the surface of the seed layer to a wet treatment solution including one or more electroplating leveling compounds. In some implementations, exposing the surface of the seed layer to the one or more oxidizing agents or other chemical reagents includes exposing the surface of the seed layer to a dry treatment including an oxygen plasma or ozone. In some implementations, exposing the surface of the seed layer to the one or more oxidizing agents or other chemical reagents includes exposing the surface of the seed layer to a thermal treatment with forming gas.

Another aspect involves an electroplating apparatus. The electroplating apparatus includes an electroplating chamber configured to hold a copper electroplating solution, a nanotwinned copper electroplating chamber configured to hold a nanotwinned copper electroplating solution, a power supply, and a controller. The controller is configured with instructions to perform the following operations: electroplating a copper feature on a substrate in the electroplating chamber, exposing a surface of the copper feature to one or more oxidizing agents or other chemical reagents to treat the copper feature, and electroplating nanotwinned copper on the copper feature in the nanotwinned copper electroplating chamber.

In some implementations, exposing the surface of the copper feature with the one or more oxidizing agents or other chemical reagents occurs as a post-treatment in the electroplating chamber or as a pre-treatment in the nanotwinned copper electroplating chamber. In some implementations, the electroplating apparatus further includes a spin rinse drying chamber configured to hold the one or more oxidizing agents or other chemical reagents, where exposing the surface of the copper feature with the one or more oxidizing agents or other chemical reagents occurs in the spin rinse drying chamber. In some implementations, the electroplating apparatus further includes a treatment chamber configured to hold the one or more oxidizing agents or other chemical reagents, where exposing the surface of the copper feature with the one or more oxidizing agents or other chemical reagents occurs in the treatment chamber. In some implementations, the one or more oxidizing agents or other chemical reagents include a wet treatment solution including an aqueous solution of a peroxide, sulfuric acid, dissolved ozone, or combinations thereof. In some implementations, the chemical reagents include one or more compounds that are stable in a solution also containing a strong oxidizer that supports the solubility of oxidized copper ions. In some implementations, the one or more oxidizing agents or other chemical reagents include a dry treatment including thermal treatment with forming gas.

Another aspect involves an electroplating apparatus. The electroplating apparatus includes an electroplating chamber fluidically connected to two or more solution reservoirs, the two or more solution reservoirs configured to hold a nanotwinned copper electroplating solution and a copper electroplating solution. The electroplating apparatus further includes a power supply and a controller configured with program instructions for performing the following operations: electroplating a copper feature on a substrate in the electroplating chamber, exposing a surface of the copper feature to one or more oxidizing agents or other chemical reagents to treat the copper feature, and electroplating nanotwinned copper on the copper feature in the electroplating chamber.

In some implementations, the two or more solution reservoirs are configured to hold a wet treatment solution, where exposing the surface of the copper feature to the one or more oxidizing agents or other chemical reagents is performed in the electroplating chamber. In some implementations, the one or more oxidizing agents or other chemical reagents include a wet treatment solution including an aqueous solution of a peroxide, sulfuric acid, dissolved ozone, or combinations thereof. In some implementations, the one or more oxidizing agents or other chemical reagents include a wet treatment solution including one or more electroplating leveling compounds.

Another aspect includes a semiconductor device. The semiconductor device includes a substrate, a dielectric layer over the substrate, and an electrically conductive interconnect structure formed in the dielectric layer. The electrically conductive interconnect structure includes a non-nanotwinned copper feature formed at least partially in the dielectric layer and a nanotwinned copper feature over the non-nanotwinned copper feature.

In some implementations, the non-nanotwinned copper feature occupies 20 vol. % or less of the electrically conductive interconnect structure. In some implementations, the non-nanotwinned copper partially or completely fills recesses in the dielectric layer, where the non-nanotwinned copper feature occupies a base of the electrically conductive interconnect structure and the nanotwinned copper feature occupies an upper portion of the electrically conductive interconnect structure.

Another aspect involves a method of forming a nanotwinned copper via and one or more nanotwinned copper lines. The method includes electroplating nanotwinned copper in a recessed region of a substrate and in regions outside the recessed region of the substrate, and electroplating non-nanotwinned copper on the nanotwinned copper to at least fill the recessed region. A filled recessed region defines a copper via, and plated regions outside the recessed region define one or more copper lines.

In some implementations, the regions outside the recessed region include a patterned photoresist layer, and electroplating nanotwinned copper in the regions outside the recessed region include electroplating nanotwinned copper in regions defined by the patterned photoresist layer. In some implementations, electroplating non-nanotwinned copper on the nanotwinned copper includes electroplating non-nanotwinned copper in the regions outside the recessed region, where electroplated non-nanotwinned copper above a depth defined by a top surface of the nanotwinned copper in the regions outside of the recessed region define a copper overburden. In some implementations, the method further includes removing all or some of the copper overburden. In some implementations, removing all or some of the copper overburden includes contacting the copper overburden with an etching solution comprising an oxidizing agent. In some implementations, electroplating nanotwinned copper includes electroplating nanotwinned copper in the regions outside the recessed region to a target thickness so that each of the one or more copper lines is formed at the target thickness. In some implementations, electroplating nanotwinned copper includes contacting a surface of the substrate with a nanotwinned copper electroplating solution, and applying a first current to the substrate when the surface of the substrate is contacted with the nanotwinned copper electroplating solution to electroplate the nanotwinned copper having a plurality of nanotwins. The nanotwinned copper electroplating solution is free of accelerators. The first current includes a pulsed current waveform that alternates between a constant current and no current. In some implementations, electroplating non-nanotwinned copper includes contacting an exposed surface of the nanotwinned copper with a copper electroplating solution, where the copper electroplating solution includes at least one or more accelerators, and cathodically biasing the substrate to fill at least the recessed region with non-nanotwinned copper.

Another aspect involves a method of forming a nanotwinned copper via and one or more nanotwinned copper lines. The method includes electroplating nanotwinned copper in a recessed region of a substrate and in regions outside the recessed region having a patterned photoresist layer, where the nanotwinned copper is electroplated to a target thickness in the regions outside the recessed region defined by the patterned photoresist layer, electroplating non-nanotwinned copper on the nanotwinned copper in the recessed region and in the regions outside the recessed region defined by the patterned photoresist layer, and removing some or all of the non-nanotwinned copper in at least the regions outside the recessed region defined by the patterned photoresist layer using an isotropic chemical etch. The nanotwinned copper and any remaining non-nanotwinned copper in the recessed region form a copper via, where the nanotwinned copper and any remaining non-nanotwinned copper in the regions outside the recessed region defined by the patterned photoresist layer form one or more copper lines.

Another aspect involves an electroplating apparatus. The electroplating apparatus includes an electroplating chamber configured to hold a copper electroplating solution, a nanotwinned copper electroplating chamber configured to hold a nanotwinned copper electroplating solution, a power supply, and a controller. The controller is configured with program instructions for performing the following operations: electroplate nanotwinned copper in a recessed region of a substrate and in regions outside the recessed region of the substrate, and electroplate non-nanotwinned copper on the nanotwinned copper to at least fill the recessed region, where a filled recessed region defines a copper via, and where plated regions outside the recessed region define one or more copper lines.

In some implementations, the regions outside the recessed region include a patterned photoresist layer, where the controller configured with instructions to electroplate the nanotwinned copper is configured with instructions to electroplate nanotwinned copper in regions defined by the patterned photoresist layer to a target thickness so that each of the one or more copper lines is formed at the target thickness. In some implementations, the copper electroplating solution includes accelerators and suppressors, and wherein the nanotwinned copper electroplating solution is free of accelerators.

Another aspect involves a semiconductor device. The semiconductor device includes a substrate, a dielectric layer over the substrate, a copper via formed in the dielectric layer, where the copper via includes a non-nanotwinned copper layer formed over a nanotwinned copper layer, and one or more copper redistribution layer (RDL) lines formed over the dielectric layer, where the one or more copper RDL lines are composed substantially of nanotwinned copper.

In some implementations, the non-nanotwinned copper layer fills recesses in the dielectric layer. In some implementations, the nanotwinned copper layer has less film stress than the non-nanotwinned copper layer.

These and other aspects are described further below with reference to the drawings.

### BRIEF DESCRIPTION OF THE DRAWINGS

FIG. 1 shows a cross-sectional scanning electron microscopy (SEM) image of a nanotwinned copper feature with a transition region.

FIGS. 2A-2C show cross-sectional schematic illustrations of various stages in an example process flow for copper damascene fill.

FIGS. 3A-3B show cross-sectional schematic illustrations of various stages in an example process flow for a 2-in-1 via and pillar.

FIG. 4 shows a cross-sectional SEM image of a nanotwinned copper feature electroplated in a 2-in-1 via and pillar.

FIG. 5 shows a flow diagram of an example method of depositing nanotwinned copper on a plated copper feature according to some implementations.

FIGS. 6A-6C show cross-sectional schematic illustrations of various stages in an example process flow for depositing nanotwinned copper in a 2-in-1 via and pillar according to some implementations.

FIGS. 7A-7E show cross-sectional schematic illustrations of various stages in an example process flow for depositing nanotwinned copper on plated copper according to some implementations.

FIG. 8 shows a cross-sectional SEM image of a nanotwinned copper feature with a minimized transition region according to some implementations.

FIGS. 9A-9B show cross-sectional schematic illustrations of various stages in depositing nanotwinned copper in a 2-in-1 via and RDL.

FIG. 10 shows a cross-sectional schematic illustration of a multilayer via and RDL structure with topographical variations resulting from conformally deposited nanotwinned copper.

FIG. 11 shows a flow diagram of an example method of depositing a nanotwinned copper via and one or more nanotwinned copper lines according to some implementations.

FIGS. 12A-12D show cross-sectional schematic illustrations of various stages in depositing nanotwinned copper and non-nanotwinned copper in a 2-in-1 via and RDL.

FIG. 13 shows a schematic diagram of an example of an electroplating cell in which electroplating may occur according to some implementations.

FIG. 14 shows a schematic of a top view of an example integrated system for performing electroplating and surface pretreatment operations according to some implementations.

FIG. 15 shows a schematic of a top view of an alternative example integrated apparatus for performing electroplating and surface pretreatment operations according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

### Introduction

Advancements in materials, processing, and equipment have led to innovations in packaging technologies. Wafer level packaging, bumping, redistribution layers, fan out, and through-silicon vias are some of the techniques employed in advanced packaging. In many cases, integrated circuit packaging involves wafer level packaging (WLP), which is an electrical connection technology that employs relatively large features, typically on the scale of micrometers. Examples of WLP features include redistribution wiring, bumps, and pillars. Such features in WLP applications and advanced packaging applications may include copper. Copper is generally used in metal connecting devices because of its high electrical conductivity, thermal transferring ability, and low cost.

In a typical electroplating process, a substrate is cathodically biased and is brought in contact with an electroplating solution containing ions of a metal that is being plated. Ions of the metal are electrochemically reduced at the surface of the substrate to form a metal layer. The metal layer may be a copper layer. Electroplated copper of the present disclosure may be used in wafer level packaging applications, heterogeneous integration applications, and advanced packaging applications.

### Nanotwinned Copper

Crystal defects may be introduced in a material that can influence mechanical, electrical, and optical properties of the material. Twinning may occur in a material where two parts of a crystal structure are symmetrically related to one another. In a face-centered cubic (FCC) crystal structure, of which copper is included, coherent twin boundaries may be formed as (111) mirror planes from which the normal stacking sequence of (111) planes is reversed. In other words, adjacent grains are mirrored across coherent twin boundaries in a layered (111)-structure. Twins grow in a layer-by-layer manner extending along a lateral (111) crystal plane where a twin thickness is on the order of nanometers, hence the name “nanotwins.” Nanotwinned copper (nt-Cu) exhibits excellent mechanical and electrical properties and may be used in a wide variety of applications in wafer level packaging, heterogeneous integration, and advanced packaging designs.

Compared to copper having conventional grain boundaries, nanotwinned copper possesses strong mechanical properties including high strength and high tensile ductility. The stronger mechanical properties may be attributable to the presence of twins acting as stress relieving mechanisms to stabilize microstructure and increase the strength of the nanotwinned copper film. Nanotwinned copper also demonstrates high electrical conductivity, which may be attributable to the twin boundary causing electron scattering that is less significant compared to a grain boundary. Furthermore, nanotwinned copper exhibits high thermal stability, which may be attributable to the twin boundary having excess energy on the order of magnitude lower than that of a grain boundary. In addition, nanotwinned copper enable high copper atom diffusivity, which is useful for copper-to-copper direct bonding. Nanotwinned copper also shows high resistance to electromigration, which may be a result of twin boundaries slowing down electromigration-induced atomic diffusion. Nanotwinned copper demonstrates a strong resistance to seed etch that may be important in fine-line redistribution layer applications. Nanotwinned copper also shows low impurity incorporation, which results in fewer Kirkendall voids as a result of soldered reactions with the nanotwinned copper.

In some implementations, nanotwinned copper enables direct copper-copper bonding. Such copper-copper bonding may occur at low temperatures, moderate pressures, and lower bonding forces/times. Typically, deposition of copper structures results in rough surfaces. In some implementations, prior to copper-copper bonding, electrodeposition of nanotwinned copper may be followed by an electropolishing process to achieve smooth surfaces. With the smooth surfaces, the nanotwinned copper structure may be used in copper-copper bonding with shorter bonding times, lower temperatures, and fewer voids.

A copper feature having nanotwinned grain structures may be formed according to a certain electroplating chemistry, waveform, and conditions. A surface of a substrate may be contacted with an electroplating solution. A current may be applied to the substrate, where the current has a pulsed waveform. The pulsed waveform alternates between a constant current (Iₒₙ) and no current (I_{off}) in a series of cycles. The duration of no current being applied per cycle is greater than a duration of the constant current being applied per cycle. For example, the duration of no current being applied per cycle may be at least three times longer than the duration of constant current being applied per cycle. In some implementations, the pulsed waveform may be followed by a constant current waveform to complete electrodeposition of the copper feature. The electroplating solution may include a copper salt, an acid, and organic additives. Example organic additives typically include accelerators, suppressors, and/or levelers. Details regarding an electroplating solution with organic additives can be described in U.S. patent application Ser. No. 13/753,333, filed Jan. 29, 2013, and titled “LOW COPPER ELECTROPLATING SOLUTIONS FOR FILL AND DEFECT CONTROL,” now issued U.S. Pat. No. 10,214,826, which is incorporated herein by reference in its entirety and for all purposes. However, the electroplating solution for depositing nanotwinned copper may be free or substantially free of accelerators. As used herein, “substantially free” may refer to a concentration of accelerators that is equal to or less than about 5 ppm. In some implementations, a concentration of accelerators is between about 0 ppm and about 5 ppm, and a concentration of suppressors is between about 30 ppm and about 300 ppm. The flow velocity or flow rate of the electroplating solution provided to the substrate may be controlled, where lower flow velocities or flow rates may promote formation of nanotwins in the copper feature. In some implementations, for example, the flow velocity of the electroplating solution in a direction parallel to a plating surface of the substrate may be between about 30 cm/s and about 70 cm/s.

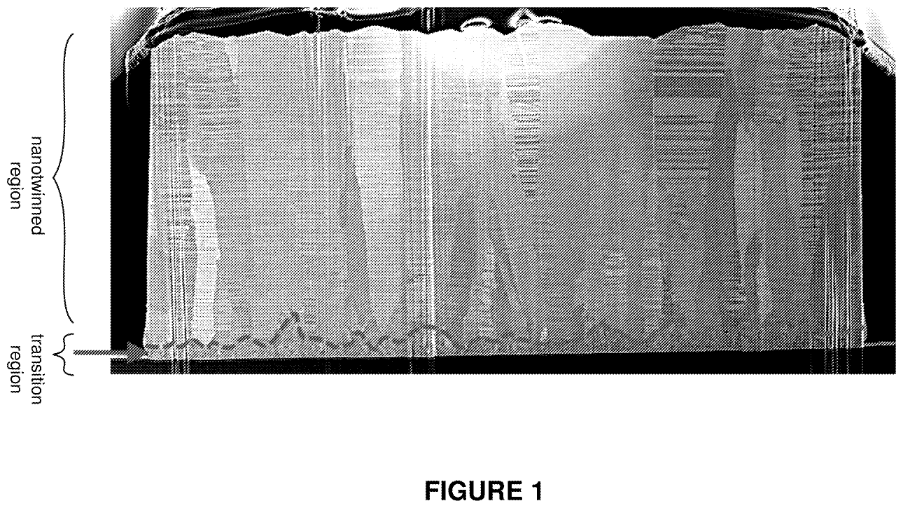

As described above, the copper feature may be grown in an accelerator-free nanotwinned copper electroplating solution epitaxially on the substrate by performing electroplating using a pulsed waveform. The pulsed waveform may or may not be followed by a constant current (Iₒₙ) waveform. Examples of more complex waveforms include current ramp, two or more constant levels and off, and multiple relatively short constant current on (Iₒₙ) and current off (I_{off}) steps, followed by a longer off time step greater than three times the length of the prior steps. The surface of the substrate on which the copper feature is formed may include a copper seed layer, non-copper seed layer (e.g., cobalt seed layer), diffusion barrier layer, liner layer, adhesion layer, plated non-nanotwinned copper layer, or other material layer. The aforementioned electroplating chemistry, waveform, and conditions may form a copper feature such as a copper feature shown in FIG. 1, where the copper feature includes a nanotwinned region and a transition region.

FIG. 1 shows a cross-sectional scanning electron microscopy (SEM) image of a nanotwinned copper feature with a transition region. The copper feature may include a nanotwinned region and a transition region underlying the nanotwinned region. The transition region may occupy a space between the nanotwinned region and the surface of the substrate on which the nanotwinned copper feature is formed. The nanotwinned region may encompass a substantial fraction of the copper feature (e.g., more than 50% of a cross-sectional area of the copper feature). The nanotwinned region may include several nanotwinned grain structures, whereas the transition region may include several randomly-oriented grain structures. Nanotwinned grain structures may be characterized by several columnar grain structures containing densely packed nanotwins.

The presence of nanotwinned grain structures can be observed using any suitable microscopy technique such as an electron microscopy technique. In the nanotwinned region, the copper feature includes several submicron-sized grains that are tall and columnar in the nanotwinned region. For example, the grains may have a diameter between about 1 nm and about 1000 nm. As shown in FIG. 1, the grains are highly columnar and have a high density of grown-in nanotwins. The highly columnar grains may have a relatively large diameter and relatively large height. For example, an average diameter of the highly columnar grains may be between about 0.2 μm and about 20 μm, and an average height of the highly columnar grains may be between about 1 μm and about 200 μm. A high density of nanotwins is observed by a high density of twin lamellar structures parallel to each other or at least substantially parallel to each other. A pair of adjacent dark and light lines may constitute a nanotwin, and nanotwins may stack along a stacking direction (e.g., along a [111] crystal axis) to form a grain. The nanotwins may be formed parallel to the (111) surface of the copper feature. Accordingly, the nanotwinned grain structures may be characterized as a plurality of (111)-oriented crystal copper grains containing a plurality of nanotwins. The (111)-oriented crystal copper grains may contain a high density of nanotwins, where a “high density of nanotwins” may refer to copper grain structures having at least several tens or hundreds of nanotwins parallel or at least substantially parallel to each other as observed using suitable microscopy techniques. Nanotwins grow in (111)-oriented crystal copper grains and stack in a layer-by-layer manner along a [111] crystal axis. An average lamella thickness in a nanotwin varies from about a few nanometers to about hundreds of nanometers. For example, an average lamella thickness can be between about 5 nm and about 100 nm. An average length of the lamellar structures may vary from tens of nanometers to tens of microns. For example, an average lamella length can be as small as 50 nm and as large as 20 μm, or the entire width of a columnar grain.

In contrast to a nanotwinned region, a transition region can be observed where grains are randomly oriented and non-nanotwinned. It will be understood that the transition region may also be referred to as a nanotwin “transition zone” or “initiation layer.” The transition region may include a plurality of fine-grained crystal structures without nanotwins. The grain structures in the transition region are small, irregularly-shaped, and randomly oriented in various crystallographic orientations, where examples of crystallographic orientations of grain structures include (110), (100), (200), (111), etc. The grain structures in the transition region vary in size and orientation and appear as a messy distribution of fine-grained crystal structures. The presence of a transition region results in poorer mechanical and electrical reliability compared to a nanotwinned copper feature without a transition region.

A transition region is formed prior to forming the nanotwinned region when initiating electrodeposition of nanotwinned copper. Even under optimal electroplating conditions, the nanotwinned region of the nanotwinned copper feature does not initiate immediately. For instance, optimal electroplating conditions may include a pulsed waveform, low flow velocity, absence of accelerators, and/or highly-oriented or highly columnar base layer, among other configurable electroplating conditions. Regardless, it may take at least about 0.4 μm, at least about 0.5 μm, at least about 0.8 μm, at least about 1 μm, at least about 2 μm, at least about 3 μm, or at least about 5 μm of electroplating the copper feature before the copper feature fully transitions to the nanotwinned region. Accordingly, the transition region may have an average thickness of at least about 0.4 μm, at least about 0.5 μm, at least about 0.8 μm, at least about 1 μm, at least about 2 μm, at least about 3 μm, or at least about 5 μm. A thicker transition region when depositing nanotwinned copper causes greater degradation in mechanical and electrical properties in the copper feature. Thicker transition regions may present significant challenges in nanotwinned copper features having small thicknesses.

Copper features in fine line redistribution layers (RDLs), fine line interconnects, microbumps, or micropillars may have a thickness equal to or less than about 5 μm. Such copper features may be critical in heterogeneous integration applications. Heterogeneous integration uses packaging technology to integrate dissimilar chips and devices. While similar to system-in-chip packaging technology, heterogeneous integration uses finer pitches, more inputs/outputs, higher density, and higher performance applications. For a copper feature that has a thickness equal to or less than about 5 μm, the transition region may occupy a significant portion of the copper feature. In some instances, the transition region consumes an entirety or almost an entirety of the copper feature. This means that the nanotwinned region occupies a smaller percentage of the copper feature or may even never form. As a result, this reduces the performance and reliability of the copper feature.

### Nanotwinned Copper in Damascene Fill

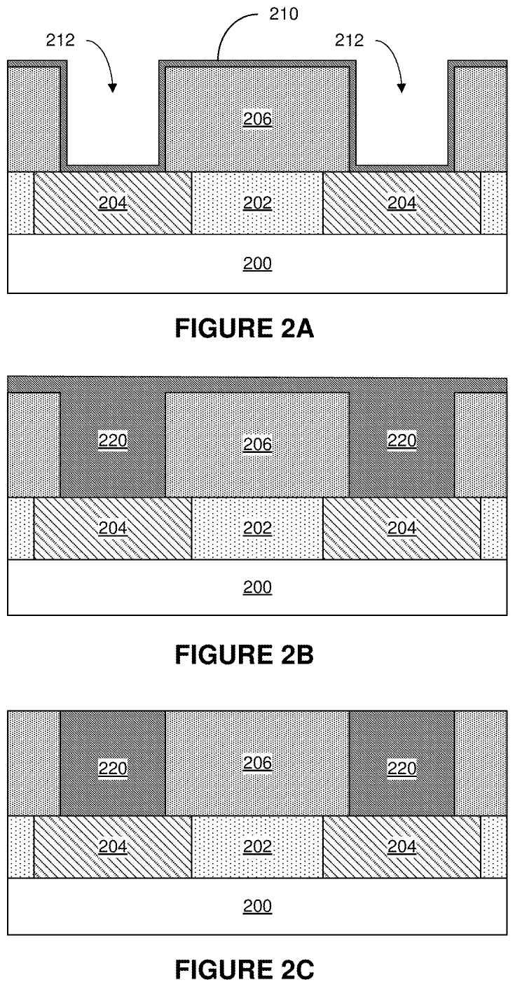

FIGS. 2A-2C show cross-sectional schematic illustrations of various stages in an example process flow for copper damascene fill. In FIGS. 2A-2C, an example substrate 200 used for damascene processing is illustrated. In some implementations, the substrate 200 may be a semiconductor wafer, built on a semiconductor wafer, or part of a semiconductor wafer. In some implementations, the substrate 200 is a silicon substrate. A passivation layer 202 may be positioned over the substrate 200, where the passivation layer 202 may include an electrically insulating material such as silicon oxide (SiO₂) or silicon nitride (SiN). The passivation layer 202 may be patterned to define locations for electrically conductive interconnect structures 204. In some implementations, the electrically conductive interconnect structures 204 may include under bump metallization (UBM). Dielectric material may be formed over the passivation layer 202 and electrically conductive interconnect structures 204, where the dielectric material is patterned to form a patterned dielectric layer 206. The patterned dielectric layer 206 defines locations for copper vias/features in a copper damascene process. The patterned dielectric layer 206 may expose top surfaces of the electrically conductive interconnect structures 204. In FIGS. 2A-2C, a diffusion barrier layer and/or liner layer (not shown) may line the patterned dielectric layer 206.

In FIG. 2A, a copper seed layer 210 is deposited over the substrate 200. The copper seed layer 210 is ideally deposited conformally, following the surface topography with sufficiently thick uniformity along sidewalls and surfaces of the patterned dielectric layer 206 and at bottoms of recesses 212. In other words, the copper seed layer 210 is deposited in field regions outside recesses 212 and in recesses 212 covering an exposed interface with sufficient thickness uniformity to allow for plating on various exposed surfaces. The copper seed layer 210 is conformal and continuous along the patterned dielectric layer 206 and on top surfaces of the electrically conductive interconnect structures 204 in the recesses 212. The recesses 212 may be defined by the patterned dielectric layer 206. It will be understood that recesses 212 may also be referred to as trenches, holes, cavities, openings, recessed features, or etched features. The recesses 212 are formed over the electrically conductive interconnect structures 204. In some implementations, the recesses 212 may have a high aspect ratio (depth-to-width aspect ratio). In some implementations, the aspect ratio of each of the recesses 212 may be equal to or greater than about 3:1, equal to or greater than about 4:1, equal to or greater than about 5:1, equal to or greater than about 8:1, equal to or greater than about 10:1, equal to or greater than about 15:1, equal to or greater than about 20:1, or equal to or greater than about 30:1.

In FIG. 2B, the recesses 212 are filled with copper to form copper features 220. Copper is deposited over the copper seed layer 210 in each of the recesses 212. In some implementations, the recesses 212 are filled with copper by performing electroplating. The substrate 200 may be contacted with electroplating solution in an electroplating chamber, and the substrate 200 may be cathodically biased to electroplate copper on the copper seed layer 210 and electrochemically fill the recesses 212 with copper. In some implementations, the electroplated copper may form an overburden over the patterned dielectric layer 206.

In performing electroplating to fill the recesses 212, the electroplating solution may contain organic additives to promote bottom-up fill of the recesses 212. Organic additives may be important in achieving desired metallurgy, film uniformity, defect control, and fill performance. Such organic additives typically include a suppressor and an accelerator and possibly a leveler. As used herein, a leveler may also be referred to as an electroplating leveling compound. As used herein, many additive concentrations are recited in parts per million (ppm).

While not wishing to be bound by any theory or mechanism, it is believed that suppressors are used to suppress electroplating and increase the surface polarization of the plating substrate. The suppressor both (1) increases the local polarization of the substrate surface at regions where the suppressor is present relative to regions where the suppressor is absent, and (2) increases the polarization of the substrate surface generally. The increased polarization (local and/or general) corresponds to increased charge transfer resistance and interfacial resistivity/impedance generally and therefore slower plating at a particular applied potential. Suppressors are often relatively large molecules, and in many instances, they are polymeric in nature (e.g., polyethylene oxide, polypropylene oxide, polyethylene glycol, polypropylene glycol, etc.). Due in part to suppressors' large size, the diffusion of these compounds into a recessed feature can be relatively slow.

While not wishing to be bound by any theory or mechanism of action, it is believed that accelerators (either alone or in combination with other bath additives) tend to locally reduce the polarization effect associated with the presence of suppressors, and thereby locally increase the electrodeposition rate. The reduced polarization effect is most pronounced in regions where the adsorbed accelerator is most concentrated (i.e., the polarization is reduced as a function of the local surface concentration of adsorbed accelerator). Example accelerators include, but are not limited to, sulfur-containing compounds, such as, dimercaptopropane sulfonic acid, dimercaptoethane sulfonic acid, mercaptopropane sulfonic acid, mercaptoethane sulfonic acid, bis-(3-sulfopropyl) disulfide (SPS), and their derivatives. Although the accelerator may react with and become strongly chemically adsorbed to the substrate surface and be generally laterally-surface immobile during and after the plating reactions, the accelerator is generally not substantially incorporated into the film in the absence of certain other compounds selected and designed to drive the accelerator to be incorporated in the growing film (examples include certain copper electroplating leveling compounds). Thus, it is believed that the accelerator molecules generally remain on the surface as metal is deposited throughout the plating process. As a recess is filled, the local surface accelerator concentration increases within the recess largely due to a reduction in cavity surface area. Accelerators tend to be smaller molecules and exhibit faster diffusion to the general surface and into recessed features, as compared to larger molecules such as suppressors. Without being limited by any theory, it is believed that the lack of incorporation into the film and general propensity for the accelerator molecules to stay at the surface and remain largely unchanged and surface active is due to their (1) strong reaction or sticking coefficient of a mercapto class or similar compounds with the copper surface, (2) only being displaced during a direct reduction of copper ion when sufficient energy is applied to or near the accelerator's binding site, and (3) ability to temporarily create a high energy physically adsorbed accelerator-species that can either (i) desorb or (ii) move to a new surface site and react at that site. If the molecule is desorbed, at ambient temperatures, most of the accelerator molecules will hit the surface again before diffusing away, and so, with such a great sticking coefficient it is believed they will find a new binding (but different than prior) site, and remain at the general surface throughout the plating process. If accurate, this model can be important in illustrating the potential difficulty in removing accelerators from a surface by wet electrolytic and wet oxidative etching processes.

While still not wishing to be bound by any theory or mechanism of action, it is believed that levelers (either alone or in combination with other bath additives) act as suppressing agents to counteract the depolarization effect associated with accelerators, especially in the field region and at the side walls of a feature. The leveler may locally increase the polarization/surface resistance of the substrate, thereby slowing the local electrodeposition reaction in regions where the leveler is present. With regard to the theory of accelerators having a strong tendency to stay at the surface during plating, certain electroplating leveling compounds may retard and increase the charge transfer resistance by themselves, while others may render accelerator molecules inactive, aid in having accelerator molecules incorporated into a plated film, or otherwise remove accelerator molecules from a general surface while plating copper. In some instances, the change in surface electrical and chemical characteristics arising from the change in accelerator surface presence occurs in the presence of an electroplating solution containing a suppressor. The local concentration of levelers and the concentration of levelers that reaches a surface is determined to some degree by mass transport. Therefore, levelers act principally on surface structures having geometries that are more exposed or protrude away from the surface. This plating-inhibiting action retards growth from exposed regions which otherwise naturally grow at a higher rate. This plating-inhibiting action can even be sufficiently large as to reduce the local exposed surface growth rate relative to more recessed regions of the surface, and thereby “smooths” the surface of the electrodeposited layer. Leveler compounds are generally classified as levelers based on their electrochemical function and impact and do not require specific chemical structure or formulation. However, levelers often contain one or more nitrogen-containing groups, such as, amine, imide or heterocycle (e.g., imidazole), and may additionally or alternatively contain sulfur functional groups in the compound. Certain levelers include one or more five and six member rings and/or conjugated organic compound derivatives. Nitrogen groups may form part of the ring structure. In amine-containing levelers, the amines may be primary, secondary or tertiary alkyl amines. Furthermore, the amine may be an aryl amine or a heterocyclic amine. Example amines include, but are not limited to, dialkylamines, trialkylamines, arylalkylamines, triazoles, imidazole, triazole, tetrazole, benzimidazole, benzotriazole, piperidine, morpholines, piperazine, pyridine, oxazole, benzoxazole, pyrimidine, quonoline, and isoquinoline. Imidazole and pyridine may be especially useful. Leveler compounds may also include ethoxide groups. For example, the leveler may include a general [O—(CH₂)ₙ]ₘ backbone, where n and m are integer values, that is similar to that found in polyethylene glycol or polyethylene oxide, with fragments of amine functionally inserted over the chain (e.g., Janus Green B). Some leveler compounds may be polymeric, while some leveler compounds are monomeric/non-polymeric. In some implementations, leveler compounds are polymeric. Example polymeric leveling agents include polyethylenimine, polyamidoamines, and reaction products of an amine with various-epoxides or sulfides. Examples of amines are described above. Example epoxides include, but are not limited to, epihalohydrins such as epichlorohydrin and epibromohydrin, and polyepoxide compounds. Polyepoxide compounds having two or more epoxide moieties joined together by an ether-containing linkage may be especially useful. One example of a non-polymeric leveler is 6-mercapto-hexanol. Another example leveler is polyvinylpyrrolidone (PVP).

In a bottom-up fill mechanism, the recesses 212 tend to be plated with copper from the bottom to the top of the recesses 212, and inward from the sidewalls towards the center of the recesses 212. The presence of accelerators and suppressors during the initial plating stages promotes rapid plating from the bottom of the recesses 212 upwards and from the sidewalls inwards. Thus, in the initial plating stages, plating occurs relatively faster within the recesses 212 and relatively slower in the field regions outside the recesses 212. As plating continues, the recesses 212 fill with copper and the surface area within the recesses 212 is reduced. Because of the decreasing surface area and the accelerators substantially remaining on the surface, the local surface concentration of accelerators within the recesses 212 increases as plating continues. This increased accelerator concentration within the recesses 212 helps maintain the differential plating rate beneficial for bottom-up fill. Thus, the use of suppressors and accelerators and possibly levelers allow the recesses 212 to be filled without voids from the bottom-up and from the sidewalls-inward.

In FIG. 2C, the copper overburden may be removed by a planarization process such as chemical mechanical polishing (CMP), chemical etching, electrochemical mechanical polishing, electropolishing, or combinations of these or other processes. That way, copper features 220 are formed in the recesses 212 over each of the electrically conductive interconnect structures 204. The planarization process may provide coplanarity among the copper features 220 across the substrate 200 and also reduce surface roughness. In some implementations, the copper features 220 serve as copper damascene interconnects or vias. In some implementations, the copper features 220 serve as copper pads in direct bonding interconnect (DBI) applications.

Electroplating nanotwinned copper in copper damascene fill as illustrated in FIGS. 2A-2C presents certain challenges. Specifically, an electroplating solution in electroplating nanotwinned copper may be free or substantially free of accelerators. While not wishing to be bound to any particular theory or model, it is believed that (1) it is necessary for any accelerators on the surface to be removed or otherwise rendered inactive prior to nanotwin plating occur, which can allow the appropriate conditions for grain-oriented nucleation of nanotwin plating to occur, and (2) the plating occurs from a solution that is free or substantially free of accelerator molecules and may contain suppressors favorable for nanotwinning growth. The lack of accelerators in the electroplating solution for nanotwinned copper may promote electroplating that is much more conformal and with little (if any) anti-conformal or bottom-up characteristics. Conformal feature filling is undesirable as it generally leads to the formation or incorporation of seams and/or voids in the copper features 220. This reduces the performance and reliability of the copper features 220 when electroplating nanotwinned copper in damascene fabrication.

Nanotwinned Copper in 2-in-1 Features

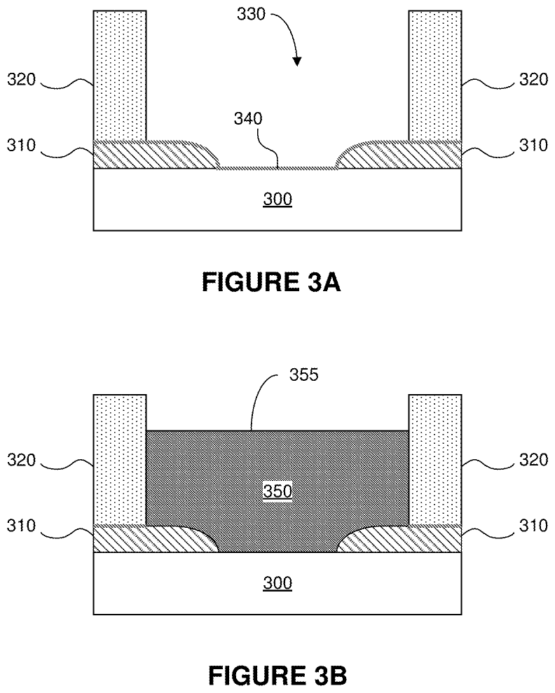

FIGS. 3A-3B show cross-sectional schematic illustrations of various stages in an example process flow for a 2-in-1 via and pillar. In FIGS. 3A-3B, an example substrate 300 used for 2-in-1 fabrication is illustrated. In some implementations, the substrate 300 may be a semiconductor wafer, built on a semiconductor wafer, or part of a semiconductor wafer. In some implementations, the substrate 300 is a silicon substrate.

Typically, copper features such as copper pillars may be formed by depositing copper in openings of patterned photoresist. The patterned photoresist may be positioned over the substrate and a copper seed layer may be positioned between the substrate and the patterned photoresist. The openings in the patterned photoresist may expose the copper seed layer at a bottom of each opening. Nanotwinned copper may be deposited on the copper seed layer by electroplating. The patterned photoresist may be subsequently removed, thereby leaving a nanotwinned copper feature such as a nanotwinned copper pillar.

A 2-in-1 feature is fabricated by providing a topographical structure between the patterned photoresist and substrate. The topographical structure defines a first sub-feature (e.g., via) and the patterned photoresist defines a second sub-feature (e.g., pillar) over the first sub-feature. The topographical structure provides underlying topography to the second sub-feature. Examples of 2-in-1 features include but are not limited to a 2-in-1 via and pillar and a 2-in-1 via and RDL. In 2-in-1 fabrication, an electrically conductive material may fill openings in the patterned photoresist and the topographical structure. The patterned photoresist may be subsequently removed, thereby leaving a 2-in-1 feature over the topographical structure and in between spaces defined by the topographical structure.

In FIG. 3A, a substrate 300 is provided. A passivation layer 310 may be positioned over the substrate 300, where the passivation layer 310 may include an electrically insulating material such as polyimide (PI). The passivation layer 310 may be patterned to define locations for 2-in-1 features. Some portions of the passivation layer 310 may be sloped, curved, or rounded. In some implementations, one or more corners of the passivation layer 310 may be sloped, curved, or rounded. This adds topography when depositing copper over the passivation layer 310. Photoresist is formed over the passivation layer 310, where the photoresist is patterned to form a patterned photoresist 320. The passivation layer 310 and the patterned photoresist 320 provide an opening 330 through which copper is deposited to form a 2-in-1 feature. The passivation layer 310 serves as a topological structure in 2-in-1 fabrication. In some implementations, a copper seed layer 340 is deposited over the passivation layer 310 and over exposed surfaces of the substrate 300 at a bottom of the opening 330. The copper seed layer 340 is continuous and conformal along surfaces of the passivation layer 310 and the substrate 300. In some implementations, an oxide layer and/or barrier layer may be deposited on the passivation layer 310 and over exposed surfaces of the substrate 300 at the bottom of the opening 330. The barrier layer may include, for example, titanium, titanium-tungsten, tungsten, or tantalum.

In FIG. 3B, the opening 330 is filled with copper to form a 2-in-1 feature 350. Copper is deposited over the copper seed layer 340 in the opening 330. In some implementations, copper is deposited by an electrofill process such as electroplating. The substrate 300 may be contacted with electroplating solution in an electroplating chamber, and the substrate 300 may be cathodically biased to electroplate copper on the copper seed layer 340 and electrochemically fill the opening 330 with copper. The opening 330 may be partially filled, completely filled, or overfilled. The 2-in-1 feature 350 may include a via and pillar. The via and pillar are formed by electrofill of copper in the opening 330. The via may be positioned between a top surface of the substrate 300 and a bottom surface of the patterned photoresist 320, where the via is located in between spaces defined by the passivation layer 310. The pillar may be positioned over the via and over the passivation layer 310, where the pillar is located in between spaces defined by the patterned photoresist 320. The passivation layer 310 serves as underlying topography for growth of the pillar in the 2-in-1 feature 350.

One of the goals of the present disclosure is to create a 2-in-1 structure that has nanotwinned copper at an upper exposed surface 355 of the 2-in-1 feature 350 so as to facilitate copper to nanotwinned copper bonding to an adjoining structure (not shown).

Electroplating nanotwinned copper in 2-in-1 features as illustrated in FIGS. 3A-3B presents certain challenges. In particular, the underlying topography caused by the passivation layer (e.g., polyimide) during 2-in-1 fabrication adversely impacts nanotwin orientation. Nanotwins in nanotwinned copper are generally oriented parallel to the local substrate and the underlying seed layer, and so columnar grains are generally oriented perpendicular to the underlying topography and seed layer. Where the seed layer is conformal along surfaces of the passivation layer that is sloped, curved, or rounded, grain growth proceeds perpendicular to the topographical surfaces that are sloped, curved, or rounded. This can cause grain growth to proceed in many different directions and nanotwins to be oriented in many different directions.

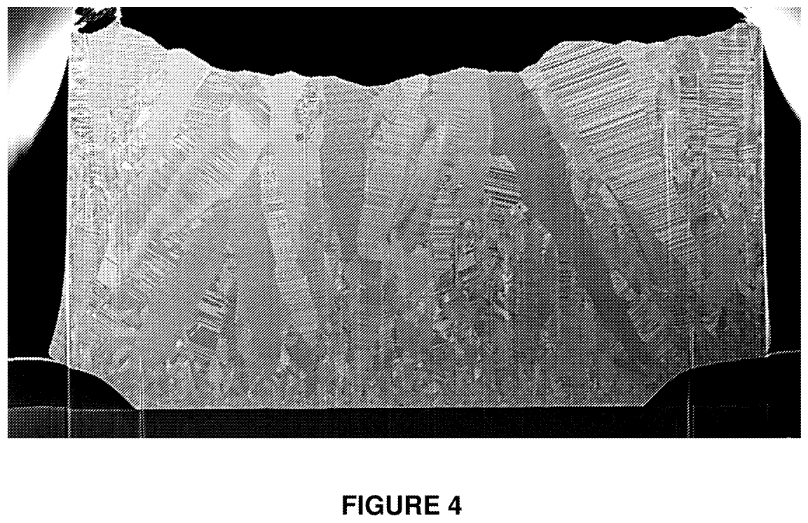

FIG. 4 shows a cross-sectional SEM image of a nanotwinned copper feature electroplated in a 2-in-1 via and pillar. A nanotwinned copper pillar is formed over a polyimide layer and defined by a patterned photoresist. The SEM image shows columnar grains extending in various angles from the polyimide layer so that nanotwins in the 2-in-1 via and pillar are arranged in various orientations. The topography in 2-in-1 fabrication results in smaller grains and fewer (111)-oriented crystal copper grains near a top surface of the 2-in-1 via and pillar than if a nanotwinned copper pillar were formed over a substrate without a polyimide layer. Smaller grains, differing nanotwin orientations, and fewer (111)-oriented crystal copper grains adversely impact the performance of the 2-in-1 via and pillar, especially in heterogeneous integration applications.

### Multi-Step Process for Electroplating Nanotwinned Copper

In the present disclosure, copper electroplating proceeds in a two-step manner. Copper is electroplated on a substrate using a copper electroplating solution to partially fill or completely fill a recessed feature of the substrate. The plated copper is not characterized as nanotwinned copper. Afterwards, nanotwinned copper is electroplated over the previously-plated copper using a nanotwinned copper electroplating solution to additionally fill the recessed feature or to deposit nanotwinned copper over a non-nanotwinned copper feature. In some implementations, the copper electroplating in a two-step manner may result in nanotwinned copper deposited on a partially-filled recessed feature of non-nanotwinned copper, or nanotwinned copper deposited on a completely-filled recessed feature of non-nanotwinned copper. This forms a hybrid or mixed crystal structure having non-nanotwinned copper and nanotwinned copper.

In some implementations, the nanotwinned copper feature of the present disclosure is formed in a two-step manner in a damascene fill process described in FIGS. 2A-2C. This mitigates voiding that would otherwise result when depositing nanotwinned copper using nanotwinned copper electroplating solution in the recessed feature. In some implementations, the nanotwinned copper feature of the present disclosure is formed in a two-step manner in a 2-in-1 fabrication process described in FIGS. 3A-3B. This mitigates grain growth in different directions and nanotwin formation in different orientations that would otherwise result when depositing nanotwinned copper using a nanotwinned copper electroplating solution.

However, it has been observed that formation of a transition region or initiation layer is exacerbated when depositing a nanotwinned copper feature in a two-step manner. In other words, by plating non-nanotwinned copper followed by nanotwinned copper, the transition region is larger than if nanotwinned copper were plated by itself (e.g., on a copper seed layer). As described earlier, transition regions reduce the performance and reliability of nanotwinned copper features especially when larger transition regions occupy more of the nanotwinned copper features.

The present disclosure minimizes the transition region when plating non-nanotwinned copper followed by nanotwinned copper in a recessed feature. As used herein, non-nanotwinned copper may be characterized as copper without nanotwins or very few nanotwins in its microstructure. In between plating non-nanotwinned copper and nanotwinned copper, a surface treatment operation is performed, where the surface treatment may refine a grain structure of the non-nanotwinned copper to promote nanotwin growth and/or remove undesired species that delay the onset of nanotwin growth (contaminants and impurities). As indicated above, such contaminants and impurities may include organic additives such as accelerators (e.g., SPS). The surface treatment includes exposing a surface of the non-nanotwinned copper to an oxidizing agent or other reactive chemistry. The reactive chemistry may be configured to remove or deactivate an accelerator and/or to refine a grain structure of the non-nanotwinned copper for promoting nanotwin growth. In some implementations, the surface treatment may include a wet treatment that involves an aqueous solution containing a peroxide (e.g., hydrogen peroxide or permanganate), sulfuric acid, or combinations thereof. In some implementations, the surface treatment may include a wet treatment that involves a solution containing one or more electroplating leveling compounds, where the solution may include deionized water or plating solution. Such a plating solution may optionally further include a copper salt, acid, and/or chloride ion, and passage of anodic (corrosion of the surface) or cathodic (plating of the surface) electrolytic current may be used. Examples of electroplating leveling compounds are discussed above. In some implementations, the surface treatment may include a wet treatment that involves an aqueous solution of dissolved ozone. For example, the dissolved ozone may be dissolved in deionized water, an acidic solution, or copper complexing solution. In some implementations, the surface treatment may include a dry treatment that involves applying gaseous ozone or an oxygen plasma. A stream with gaseous ozone may additionally contain inert carrier gases or air. In some implementations, the surface treatment may include a dry treatment that involves exposing the non-nanotwinned copper to a thermal treatment in forming gas (e.g., mixture of nitrogen and hydrogen gas). In some implementations, different surface treatments may be performed simultaneously or sequentially. The surface treatment reduces or eliminates the transition region that would otherwise form when plating the nanotwinned copper directly on the non-nanotwinned copper.

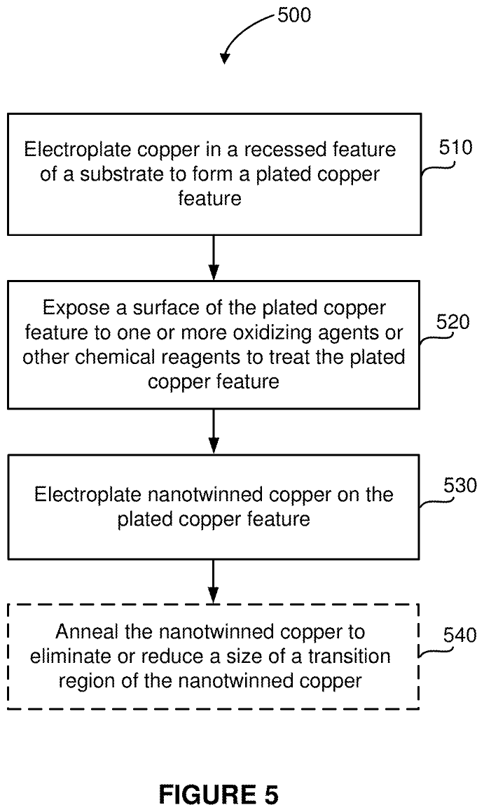

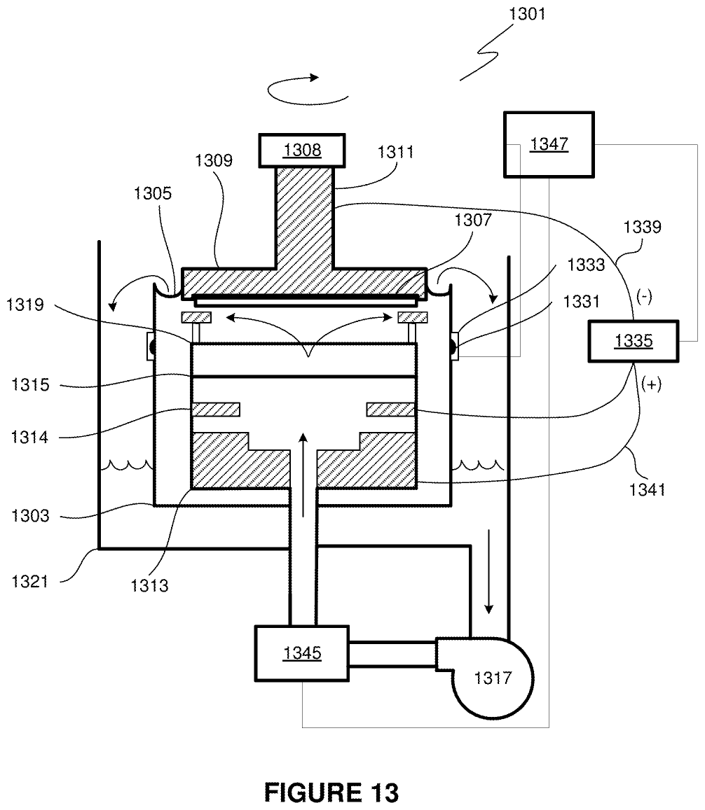

FIG. 5 shows a flow diagram of an example method of depositing nanotwinned copper on a plated copper feature according to some implementations. The operations in a process 500 may be performed in different orders and/or with different, fewer, or additional operations. In some implementations, the operations in the process 500 may be performed in an apparatus configured for electroplating. Specifically, electroplating and surface treatment operations may be performed in the same tool platform. Examples of electroplating apparatuses are described in FIGS. 13-15. One example of an electroplating apparatus is the Sabre® Electroplating System produced by and available from Lam Research Corporation of Fremont, Calif.

At block 510 of the process 500, copper is electroplated in a recessed feature of a substrate to form a plated copper feature. The substrate is provided to an electroplating apparatus. The substrate has at least one recessed feature. Examples of recessed features include but are not limited to trenches, holes, contact holes, openings, vias, gaps, cavities, and the like. These terms may be used interchangeably in the present disclosure. In some implementations, the recessed feature can have straight sidewalls, positively sloped sidewalls, or negatively sloped sidewalls. The recessed feature may have an aspect ratio (depth to lateral dimension). In some implementations, the recessed feature has an aspect ratio of at least about 1:1, at least about 2:1, at least about 3:1, at least about 4:1, at least about 5:1, at least about 8:1, at least about 10:1, at least about 15:1, at least about 20:1, or at least about 30:1.

In some implementations, the recessed feature may be defined by a patterned photoresist. For example, the recessed feature may be defined to form a copper feature such as a copper micropillar, copper microbump, or copper fine line RDL. In some implementations, the recessed feature may constitute a recess defined in a dielectric layer. For example, the recessed feature may be defined to form a copper via in a damascene structure. In another example, the recessed feature may be defined to form a copper bond pad for hybrid bonding. In some implementations, the recessed feature may be defined by openings in patterned photoresist and a passivation layer. For example, the recessed feature may be defined to form a 2-in-1 feature such as a copper via and pillar or copper via and RDL.

The plated copper feature may partially fill or completely fill the recessed feature of the substrate. In some implementations, a bottom of the recessed feature includes an underlayer such as a copper seed layer. In some implementations, sidewalls and a bottom of the recessed feature includes a liner and/or diffusion barrier layer. To electroplate copper in the recessed feature, one or more surfaces of the recessed feature are contacted with a copper electroplating solution, and the substrate is cathodically biased to at least partially fill or completely fill the recessed feature with copper to form the plated copper feature. The copper is non-nanotwinned copper. Electroplating the copper proceeds in a bottom-up fill mechanism in the recessed feature as opposed to a conformal fill mechanism. The bottom-up fill mechanism promotes formation of a plated copper feature that is without voids/seams.

The substrate is contacted with the copper electroplating solution in the electroplating apparatus. As used herein, an electroplating solution may also be referred to as an electrolyte, plating solution, plating bath, or aqueous electroplating solution. The copper electroplating solution includes at least a source of copper, an acid, and one or more organic additives to promote bottom-up fill of the plated copper feature. A concentration of each of the one or more organic additives may be between about 1 ppm and about 500 ppm, between about 2 ppm and about 300 ppm, or between about 5 ppm and about 200 ppm. The copper electroplating solution includes at least one or more accelerators (e.g., SPS).

At block 520 of the process 500, a surface of the plated copper feature is exposed to one or more oxidizing agents or other chemical reagents to treat the plated copper feature. Without being limited by any theory, the oxidizing agents or other chemical reagents may have chemistries that remove, chemically modify, or otherwise deactivate accelerator molecules (e.g., SPS) in a way to allow for nanotwin plating to occur. It is also possible that the oxidizing agents or other chemical reagents may refine the grain structure of the plated copper feature in a manner that promotes nanotwinning when forming nanotwinned copper. The substrate may be treated in a treatment chamber or station that is part of the same tool of the electroplating apparatus. Accordingly, exposing the surface of the plated copper feature to the one or more oxidizing agents or other chemical reagents occurs without introducing a vacuum break in between operations. For example, the one or more oxidizing agents or other chemical reagents can be introduced as a pre-treatment in an electroplating chamber/station for plating nanotwinned copper, as a post-treatment in an electroplating chamber/station for plating non-nanotwinned copper, as a treatment in a treatment chamber/station that is part of the same tool for electroplating nanotwinned copper and non-nanotwinned copper, or as a treatment in a spin rinse drying chamber/station that is part of the same tool for electroplating nanotwinned and non-nanotwinned copper. The sequence of processes and treatments of FIG. 5 may be performed using a sequence of modules that perform each of the individual operations described, or in one or more modules that can perform a few or all of the operations. For example, two different plating modules may be used in FIG. 5, one for plating non-nanotwinned copper and one or plating nanotwinned copper. In some instances, a separate chamber or module may be used for surface treatment, such as an ashing process chamber or thermal anneal process chamber. In some implementations, the sequence of processes and treatments of FIG. 5 may be performed using a single plating module that can perform a few or all of the operations. For example, a plating module may be used in FIG. 5, where the plating module may be fluidically connected to two or more solution reservoirs holding different solutions. The surface treatment performed at block 520 occurs after plating non-nanotwinned copper at block 510 and prior to plating nanotwinned copper at block 530.

The one or more oxidizing agents or other chemical reagents may serve to remove or render inactive contaminants and impurities from the plated copper feature. In some implementations, the one or more oxidizing agents or other chemical reagents may serve to remove or render inactive or inconsequential to nanotwin plating the one or more organic additives from the plated copper feature. For example, the one or more oxidizing agents or other chemical reagents may break down and/or remove one or more accelerators and other contaminants from the plated copper feature. In some implementations, different oxidizing agents and/or chemical reagents may be used simultaneously or sequentially. The accelerators typically contain carbon, oxygen, hydrogen, and/or sulfur, and may oxidize to create carbon dioxide (CO₂), water (H₂O), and/or sulfur dioxide (SO₂). Thereafter, the surface of the plated copper feature may be free or substantially free of accelerators. Without being limited by any theory, the presence of accelerators on a surface acts as grain refiners and modify the grain growth in a way that interferes with the growth of nanotwins. This can result in larger transition regions when forming nanotwinned copper.

In some embodiments, the chemical reagents include one or more compounds that are stable in a solution also containing a strong oxidizer that supports the solubility of oxidized copper ions. These may include but are not limited to acids with soluble anions for copper (e.g. sulfuric acid, phosphoric acid, hydrochloric acid), and copper ion complexing agents in higher pH solutions (e.g. greater than pH 5, complexing agents include, as example, ethylenediaminetetraacetic acid (EDTA), glycine, citrate, ethylene diamine) but should not include species that may strongly react directly with the copper surface (e.g. organo-mercapto compounds, benzotriazole (BTA)).

Exposing the surface of the plated copper feature to the one or more oxidizing agents or other chemical reagents can include exposing the surface of the plated copper feature to a wet treatment solution. In some implementations, the wet treatment solution includes an aqueous solution of a peroxide, sulfuric acid, or combinations thereof. In some implementations, the wet treatment solution includes a mixture of sulfuric acid and hydrogen peroxide (a “piranha etching” solution). In some implementations, the wet treatment solution includes an organic acid, an inorganic acid, a dissolved gas such as dissolved ozone in water, dissolved carbon dioxide in water, deionized water, carbonic acid, or methane sulfonic acid. In some implementations, the wet treatment solution includes a solution containing one or more electroplating leveling compounds. The solution may contain levelers alone or contain levelers in a plating solution with copper salt, acid, and halide ion (e.g., chloride ion). Any suitable oxidizing agent or reactive chemistry for removing contaminants such as accelerators may be applied without damaging the plated copper feature.

In some implementations, the wet treatment solution is delivered to the plated copper feature via a spray nozzle. The spray nozzle may be positioned in the treatment chamber or electroplating chamber to supply the wet treatment solution to the surface of the plated copper feature. In some implementations, a temperature of the wet treatment solution may be controlled. For example, the wet treatment solution may be heated to a temperature between about 20° C. and about 50° C. In some implementations, the substrate may be rotated on a substrate support while the wet treatment solution is delivered to the substrate. In some implementations, a duration of exposure may be controlled. For example, a duration of exposure to the wet treatment solution is between about 10 seconds and about 120 seconds. In some implementations, a pressure in the treatment chamber, spin rinse drying chamber, or electroplating chamber may be controlled. For example, a pressure in the chamber may be between about 25 Torr and about 100 Torr. After exposing the surface of the plated copper feature with the one or more oxidizing agents or other chemical reagents, the surface of the plated copper feature may be exposed to a cleaning agent such as deionized water to remove the wet treatment solution.

Exposing the surface of the plated copper feature to the one or more oxidizing agents or other chemical reagents can include exposing the surface of the plated copper feature to a dry treatment. In some implementations, the dry treatment includes exposing the surface of the plated copper feature to an oxygen-containing gas. In some implementations, the dry treatment includes exposing the surface of the plated copper feature to oxygen plasma or ozone. Oxygen plasma may be generated remotely or in-situ in the treatment/electroplating chamber for exposing the plated copper feature to the oxidizing agent. Radicals of oxygen such as O* and O₂⁻ are highly reactive and remove or render inactive contaminants from the plated copper feature. Ozone is a highly reactive gas that can serve to remove or render inactive contaminants from the plated copper feature. Other reactive gases and/or inert gases may be mixed with the oxidizing agent when exposing the surface of the plated copper feature to the dry treatment.

In some implementations, the dry treatment includes a thermal treatment with forming gas. The forming gas may include, for example, a mixture of nitrogen and hydrogen gas. The thermal treatment with forming gas may be performed at an elevated temperature, such as a temperature equal to or greater than about 100° C., equal to or greater than about 150° C., equal to or greater than about 200° C., or equal to or greater than about 250° C. In some implementations, the elevated temperature may be applied by heating the substrate. Without being limited by any theory, the thermal treatment with forming gas may change the grain structure of the plated copper feature that enables subsequent nanotwinning. In addition or in the alternative, without being limited by any theory, the thermal treatment with forming gas may interact with accelerators in a manner to remove or render inactive accelerators from the plated copper feature.

In some implementations, the surface of the plated copper feature may be tested to determine that the surface of the plated copper feature is free or substantially free of accelerators. Alternatively, the surface of the plated copper feature may be tested to determine that the surface of the plated copper feature has accelerators. A metrology or technique may be applied to detect the presence of accelerators on the surface of the plated copper feature to ensure that the surface of the plated copper feature is properly conditioned for nanotwin plating.

In some implementations, the surface treatment at block 520 may involve multiple surface treatments performed simultaneously or sequentially. When performed sequentially, different wet treatment solutions or different dry treatment solutions may be performed in a certain order to facilitate removal of contaminants from the surface of the plated copper feature. For example, the surface treatment at block 520 can include exposing the plated copper feature to a peroxide solution followed by a piranha etching solution. Without being limited by any theory, this kind of sequential treatment may result in a breakdown of accelerator molecules and then full removal from the surface of the plated copper feature. In another example, the surface treatment at block 520 can include exposing the plated copper feature to piranha etching solution followed by a peroxide solution. Without being limited by any theory, this kind of sequential treatment may result in substantial removal of accelerator molecules and then a longer surface clean of the plated copper feature.

At block 530 of the process 500, nanotwinned copper is electroplated on the plated copper feature. Nanotwinned copper may be plated on the plated copper feature using a nanotwinned copper electroplating solution. In some implementations, nanotwinned copper may be deposited in the recessed feature of the substrate to completely or at least additionally fill the recessed feature. In some implementations, the plated copper feature may completely fill a recessed feature, and nanotwinned copper may be electroplated as a feature (e.g., pillar) over the plated copper feature.

Electroplating nanotwinned copper at block 530 may occur in the same electroplating apparatus as electroplating the plated copper feature at block 510. In some implementations, the electroplating apparatus may include one or more plating modules, where each of the one or more plating modules are fluidly connected to two or more solution reservoirs or sources that can deliver different electroplating solutions to the electroplating apparatus. One of the solution reservoirs or sources can provide a nanotwinned copper electroplating solution. Another one of the solution reservoirs or sources can provide a non-nanotwinned copper electroplating solution (i.e., copper electroplating solution). In some embodiments, the electroplating apparatus may be configured to provide the different electroplating solutions to a single plating module where the electroplating solutions are exchanged, though it will be understood that in other embodiments the electroplating apparatus may be configured to provide the electroplating solutions to different plating modules. As such, one plating module may be configured to perform bottom-up plating at block 510, and another plating module may be configured to perform nanotwin plating at block 530. Electroplating nanotwinned copper at block 530 may also occur in the same electroplating apparatus as exposing the plated copper feature to the one or more oxidizing agents or other chemical reagents at block 520. In some embodiments, the surface treatment operation at block 520 may be performed in a plating module used to perform electroplating, where the plating module may be fluidically connected to a solution reservoir holding a wet treatment solution. In some embodiments, the surface treatment operation at block 520 may be performed in a separate chamber from the one or more plating modules in the electroplating apparatus. For example, the separate chamber may be an ashing chamber.

After plating non-nanotwinned copper in the recessed feature by a bottom-up fill mechanism, nanotwinned copper may be plated by a conformal fill mechanism. In some instances, the nanotwinned copper may be plated in the recessed feature by the conformal fill mechanism, where the nanotwinned copper may be plated in the recessed feature without forming voids/seams. The nanotwinned copper electroplating solution may include at least a source of copper and an acid. The nanotwinned copper electroplating solution may include one or more organic additives such as suppressors. However, the nanotwinned copper electroplating solution is free or substantially free of accelerators. In some implementations, the nanotwinned copper electroplating solution is also free or substantially free of levelers. In some implementations, a concentration of accelerators is between about 0 ppm and about 5 ppm, a concentration of levelers is between about 0 ppm and about 30 ppm, and a concentration of suppressors is between about 30 ppm and about 300 ppm.

To electroplate nanotwinned copper on the plated copper feature, the surface of the plated copper feature is contacted with the nanotwinned copper electroplating solution, and a first current is applied to the substrate to electroplate the nanotwinned copper having a plurality of nanotwins, where the first current includes a pulsed current waveform that alternates between a constant current and no current. The pulsed current waveform promotes formation of (111)-oriented crystal copper grains and nanotwinning. The first current is applied when cathodically biasing the substrate while the nanotwinned copper electroplating solution is contacting the surface of the plated copper feature. In some implementations, the first current provides a direct current (DC) having a current density that is between about 1 A/dm² and about 12 A/dm², between about 2 A/dm² and about 8 A/dm², or about 4 A/dm². The current density is controlled to promote formation of nanotwins. A minimum current density (e.g., 2 A/dm²) may be necessary to promote formation of nanotwins at an acceptable plating rate, and a maximum current density (e.g., 8 A/dm²) may inhibit formation of nanotwins. A duration of no current (T_{off}) being applied per cycle is substantially greater than a duration of the constant current (Tₒₙ) being applied per cycle in the pulsed current waveform. In some implementations, the duration of no current per cycle is at least three times longer than a duration of the constant current per cycle. In some implementations, the duration of no current being applied per cycle can be between about 0.3 seconds and about 8 seconds, or between about 0.4 seconds and about 6 seconds, or between about 0.5 seconds and about 5 seconds. In some implementations, the duration of constant current being applied per cycle can be between about 0.05 seconds and about 2.5 seconds, between about 0.1 seconds and about 2 seconds, or between about 0.1 seconds and about 1.5 seconds. Examples of Tₒₙ/T_{off} for the pulsed current waveform may be 0.1/0.5, 0.2/1, 0.5/2, 1/4, or 1.5/6 with a current density of about 4 A/dm². Durations for Tₒₙ/Tof may be tuned to achieve a high density of nanotwins at an acceptable plating rate. An acceptable plating rate for sufficiently high throughput applications may be at least about 0.1 μm per minute, at least about 0.15 μm per minute, at least about 0.2 μm per minute, or at least about 0.5 μm per minute. Cycles of alternating constant current and no current in the pulsed current waveform are repeated until a desired thickness is achieved. In some implementations, at least about 50 cycles are repeated, at least about 100 cycles are repeated, at least about 200 cycles are repeated, or at least about 500 cycles are repeated. In some implementations, an average thickness of the nanotwinned copper is equal to or less than about 5 μm, equal to or less than about 3 μm, or equal to or less than about 1 μm.

In some implementations, a second current is optionally applied to the substrate after the first current is applied, where the second current includes a constant current waveform. This may occur while the nanotwinned copper electroplating solution is contacting the plated copper feature. The constant current waveform provides a constant current having a current density between about 1 A/dm² and about 12 A/dm², between about 2 A/dm² and about 8 A/dm², or about 4 A/dm². A high density of nanotwins may surprisingly continue to form when transitioning from a pulsed current waveform to a constant current waveform. Thus, transitioning from a pulsed current waveform to a constant current waveform does not prevent formation of nanotwins. In some implementations, a remainder of the nanotwinned copper in the recessed feature may be formed using the constant current waveform.

In some implementations, a flow rate or flow velocity of the nanotwinned copper electroplating solution may be controlled to promote formation of nanotwins. Lower flow rates making contact with the substrate during electroplating may promote a higher density of nanotwins than higher flow rates. In some implementations, the flow velocity of the nanotwinned copper electroplating solution in a direction parallel to a plating surface of the substrate is equal to or less than about 70 cm/s or between about 30 cm/s and about 70 cm/s.

In some implementations, the plated copper feature combined with the nanotwinned copper may define a copper micropillar, copper microbump, or copper fine line RDL. In some implementations, the plated copper feature combined with the nanotwinned copper may define a copper via in a damascene structure. In some implementations, the plated copper feature combined with the nanotwinned copper may define a copper bond pad for hybrid bonding. In some implementations, plated copper feature combined with the nanotwinned copper may define a 2-in-1 feature such as a copper via and pillar or copper via and RDL.

When electroplating the nanotwinned copper on the plated copper feature, the nanotwinned copper may include a nanotwinned region having (111)-oriented nanotwinned crystal copper grains and possibly a transition region underlying the nanotwinned region. In some implementations, the nanotwinned copper is electroplated without a transition region or with a transition region having an average thickness equal to or less than about 0.5 μm, equal to or less than about 0.3 μm, or equal to or less than about 0.1 μm. The transition region is located between the nanotwinned region and the top surface of the plated copper feature. The transition region is characterized by smaller grains than the nanotwinned region and the absence of (111)-oriented nanotwinned crystal copper grains. Surface treatment removes or renders inactive contaminants and impurities from the plated copper feature so that a transition layer is eliminated or otherwise reduced when epitaxially growing nanotwinned copper on the plated copper feature. Thus, a size of the transition region in nanotwinned copper is reduced with surface treatment compared to a size of the transition region in nanotwinned copper without surface treatment.

In some implementations, the process 500 further includes planarizing the nanotwinned copper. In some implementations, planarizing the nanotwinned copper can include chemical mechanical polishing. In some implementations, planarizing the nanotwinned copper can include an electropolishing process that is characterized by electrochemical removal of materials at a surface of the nanotwinned copper. This reduces variations in coplanarity and irregularities in surface topography.

In some implementations, the nanotwinned copper may be planarized prior to bonding the nanotwinned copper in a direct bonding interconnect (DBI). In hybrid bonding, a first nanotwinned copper is electroplated in a plurality of first recessed features of a first substrate, where the first recessed features are formed in a first patterned dielectric layer. A second nanotwinned copper is electroplated in a plurality of second recessed features of a second substrate, where the second recessed features are formed in a second patterned dielectric layer. The first nanotwinned copper and the second nanotwinned copper are each formed in a two-step manner with surface pretreatment described in the present disclosure. The first nanotwinned copper of the first substrate is aligned with the second nanotwinned copper of the second substrate. A temperature of the first and second substrates is raised to cause dielectric bonding between the first patterned dielectric layer and the second patterned dielectric layer. In some implementations, the temperature for dielectric bonding is between about 30° C. and about 150° C. Thereafter, the temperature of the first and second substrates is raised to cause metal bonding between the first nanotwinned copper and the second nanotwinned copper. This forms a strong metallurgical bond between the first and second nanotwinned copper. The elevated temperature for metal bonding also serves to anneal the nanotwinned copper and reduce/eliminate any transition regions in the first and second nanotwinned copper. In some implementations, the elevated temperature for metal bonding is between about 150° C. and about 400° C. or between about 250° C. and about 350° C.

In some implementations, at block 540 of the process 500, the nanotwinned copper is optionally annealed to eliminate or reduce a size of the transition region. An annealing temperature may be greater than a deposition temperature when electroplating nanotwinned copper. In some implementations, a deposition temperature is between about 10° C. and about 45° C. In some implementations, an annealing temperature is between about 100° C. and about 400° C. or between about 150° C. and about 300° C., such as about 250° C. Annealing may be performed for a duration between about 1 minute and about 5 hours, between about 5 minutes and about 3 hours, or between about 10 minutes and about 2 hours. Without being limited by any theory, annealing the nanotwinned copper can propagate nanotwins downward into the transition region to reduce a size of the transition region. Put another way, the nanotwinned region extends into and “consumes” the transition region with thermal annealing. Thus, thermal annealing the nanotwinned copper further increases the performance and reliability of the nanotwinned copper.

In some implementations, the process 500 further includes removal of any mask or patterned photoresist. For example, patterned photoresist can be removed by photoresist stripping. The nanotwinned copper deposited on the plated copper feature may form a copper micropillar, copper microbump, or fine line copper RDL. In some implementations, the nanotwinned copper deposited on the plated copper feature may form a 2-in-1 structure such as a copper via and pillar or copper via and RDL.

Alternatively, in the present disclosure, surface treatment is performed on a seed layer prior to electroplating nanotwinned copper. Rather than performing a two-step copper plating operation, where surface treatment occurs after plating non-nanotwinned copper and prior to plating nanotwinned copper, surface treatment occurs on a seed layer to remove or render inactive various contaminants and impurities and/or change a grain structure of the seed layer for promoting nanotwin growth. In such a process flow, a method includes providing a substrate having a seed layer with one or more contaminants or crystal defects on a surface of the seed layer, exposing the surface of the seed layer to one or more oxidizing agents or other chemical reagents to treat the seed layer, and electroplating a nanotwinned copper feature on the seed layer. The seed layer may be deposited on the substrate by any suitable deposition technique such as physical vapor deposition (PVD), chemical vapor deposition (CVD), atomic layer deposition (ALD), electroplating, or electroless plating. In some implementations, the seed layer is a copper seed layer. In some implementations, the nanotwinned copper feature has a thickness equal to or less than about 5 μm, equal to or less than about 3 μm, or equal to or less than about 1 μm. In some implementations, the surface of the seed layer is exposed to a wet treatment solution including an aqueous solution of a peroxide, sulfuric acid, dissolved ozone, or combinations thereof. In some implementations, the surface of the seed layer is exposed to a wet treatment solution including one or more electroplating leveling compounds. In some implementations, the surface of the seed layer is exposed to a dry treatment including oxygen plasma or ozone. In some implementations, the surface of the seed layer is exposed to a dry treatment including thermal treatment with forming gas (e.g., mixture of nitrogen and hydrogen gas). The surface treatment minimizes a size of a transition region in the nanotwinned copper feature. For example, the nanotwinned copper feature is electroplated without a transition region or with a transition region having an average thickness less than about 0.5 μm.

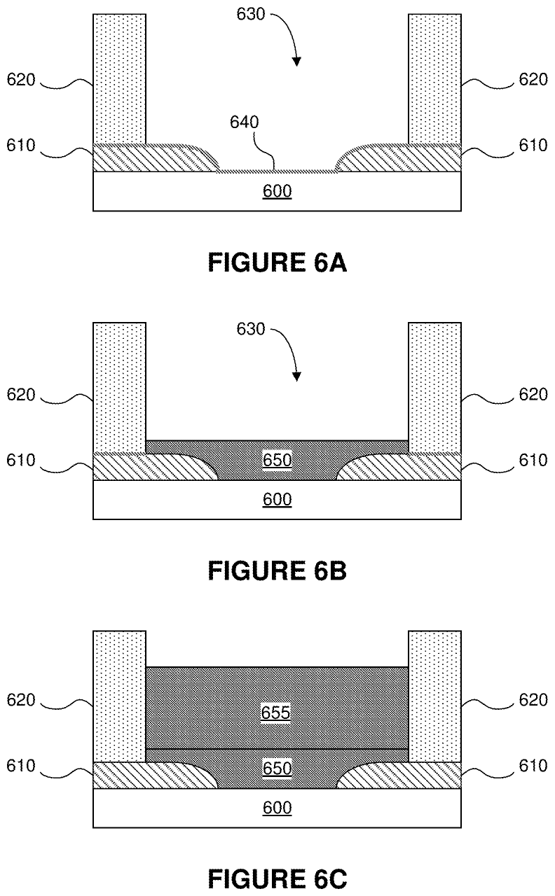

FIGS. 6A-6C show cross-sectional schematic illustrations of various stages in an example process flow for depositing nanotwinned copper in a 2-in-1 via and pillar according to some implementations. In FIGS. 6A-6C, an example substrate 600 used for 2-in-1 fabrication is illustrated. In some implementations, the substrate 600 may be a semiconductor wafer, built on a semiconductor wafer, or part of a semiconductor wafer. In some implementations, the substrate 600 is a silicon substrate. A passivation layer 610 may be positioned over the substrate 600, where the passivation layer 610 may include an electrically insulating material such as polyimide. The passivation layer 610 may be patterned to define locations for 2-in-1 features. Some portions of the passivation layer 610 may be sloped, curved, or rounded. In some implementations, one or more corners of the passivation layer 610 may be sloped, curved, or rounded. This adds topography when depositing copper over the passivation layer 610. Photoresist is formed over the passivation layer 610, where the photoresist is patterned to form a patterned photoresist 620. The passivation layer 610 and the patterned photoresist 620 provide an opening 630 through which copper is deposited to form a 2-in-1 feature. In some implementations, a copper seed layer 640 is deposited over the passivation layer 610 and over exposed surfaces of the substrate 600 at a bottom of the opening 630. The copper seed layer 640 is continuous and conformal along surfaces of the passivation layer 610 and the substrate 600. In some implementations, an oxide layer and/or barrier layer may be deposited on the passivation layer 610 and over exposed surfaces of the substrate 600 at the bottom of the opening. The barrier layer may include, for example, titanium, titanium-tungsten, tungsten, or tantalum.

In FIG. 6B, the opening 630 is partially filled with non-nanotwinned copper 650. Non-nanotwinned copper 650 is deposited by electroplating over the copper seed layer 640 in the opening 630. The substrate 600 may be contacted with copper electroplating solution in an electroplating chamber, and the substrate 600 may be cathodically biased to electroplate non-nanotwinned copper 650 on the copper seed layer 640. The copper electroplating solution contains organic additives such as accelerators to promote void-free bottom-up filling of the opening 630. The non-nanotwinned copper 650 partially fills the opening 630 to a thickness at or just above the passivation layer 610. In some implementations, the non-nanotwinned copper 650 partially fills the opening 630 to a thickness that is no more than 1 μm higher, no more than 0.5 μm higher, or no more than 0.1 μm higher than the passivation layer 610. Deposition of the non-nanotwinned copper 650 provides at least the via in the 2-in-1 via and pillar. The via is defined by the passivation layer 610 at a bottom of the opening 630. A top surface of the non-nanotwinned copper 650 is relatively flat so that subsequent deposition of nanotwinned copper in the opening 630 is not impacted by the underlying topography of the passivation layer 610. In some implementations, the top surface of the non-nanotwinned copper 650 may be planarized by a planarization process.

In FIG. 6C, the top surface of the non-nanotwinned copper 650 is treated to remove or render inactive contaminants and impurities and/or refine a grain structure of the non-nanotwinned copper 650, and nanotwinned copper 655 is deposited by electroplating over the non-nanotwinned copper 650. The top surface of the non-nanotwinned copper 650 is treated with an oxidizing agent or other reactive chemistry for removing or deactivating accelerators and/or for refining the grain structure of the non-nanotwinned copper 650. By way of an example, the oxidizing agent can include peroxide, sulfuric acid, dissolved ozone, or combinations thereof. In another example, the reactive chemistry can include levelers. In another example, the oxidizing agent can include oxygen plasma. In yet another example, the oxidizing agent can include ozone. In some implementations, the reactive chemistry includes compounds that are stable in a solution that contains a strong oxidizer that supports the solubility of oxidized copper ions. These include but are not limited to acids with soluble anions for copper (e.g., sulfuric acid, phosphoric acid, or hydrochloric acid), and copper ion complexing agents in higher pH solutions (e.g., ethylenediaminetetraacetic acid (EDTA), glycine, citrate, ethylene diamine). These generally should not include species that may strong react with the copper surface (e.g., organo-mercapto compounds, benzotriazole (BTA)). In some implementations, the reactive chemistry includes forming gas provided in a thermal treatment. The oxidizing agent or other reactive chemistry can remove or render inactive contaminants and impurities such as accelerators from the top surface of the non-nanotwinned copper 650. Alternatively or additionally, the oxidizing or other reactive chemistry can refine the grain structure of the non-nanotwinned copper 650 for promoting subsequent nanotwinning. Thereafter, the substrate 600 may be contacted with nanotwinned copper electroplating solution in an electroplating chamber, and the substrate 600 may be cathodically biased to electroplate nanotwinned copper 655 on the non-nanotwinned copper 650. The nanotwinned copper electroplating solution is free or substantially free of accelerators. The nanotwinned copper 655 may partially fill or completely fill the opening 630. The patterned photoresist 620 may be subsequently removed. The nanotwinned copper 655 plated on the non-nanotwinned copper 650 forms a 2-in-1 via and pillar. Nanotwins in the nanotwinned copper 655 are substantially uniform and parallel to the local substrate, and specifically parallel to the top surface of the non-nanotwinned copper 650. Unlike the result in FIGS. 3A-3B and FIG. 4, grain growth does not proceed in many different directions and nanotwins are not oriented in many different directions. A transition region in the nanotwinned copper 655 is minimized, where an average thickness of the transition region is less than about 0.5 μm.

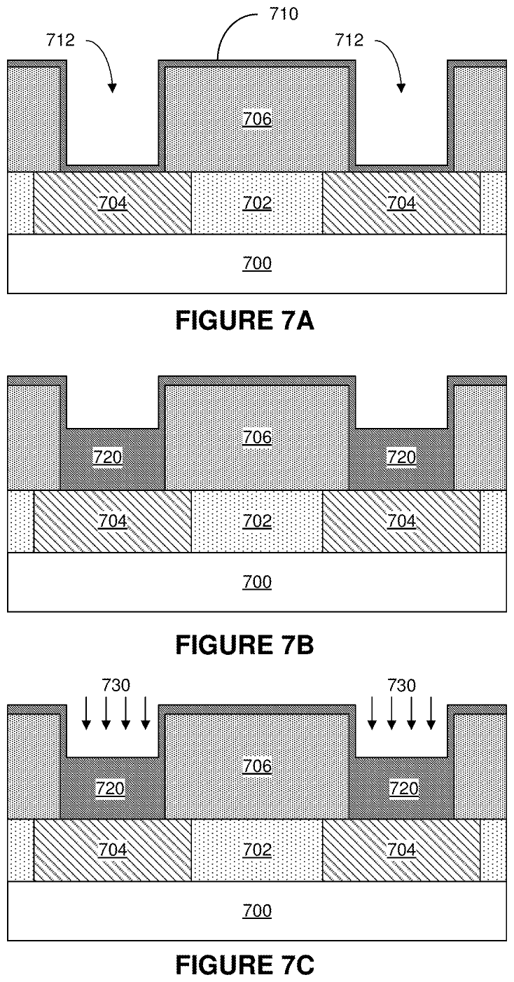

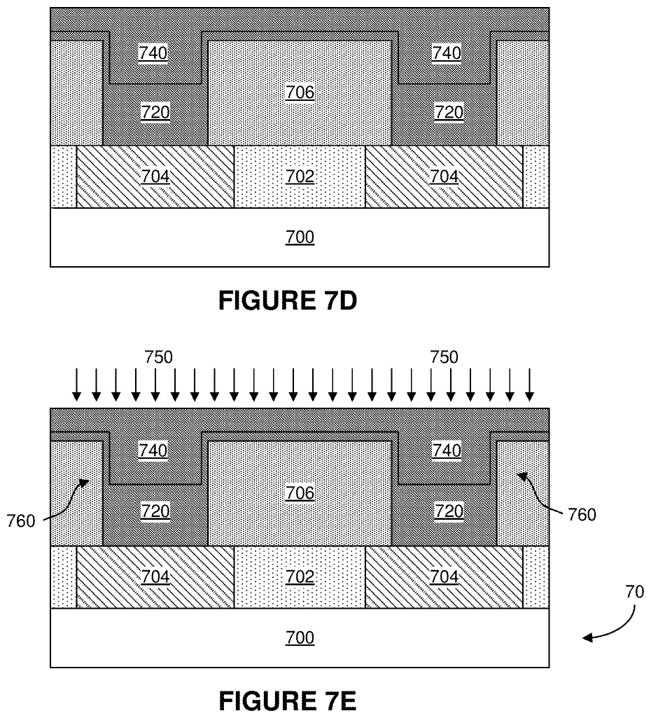

FIGS. 7A-7E show cross-sectional schematic illustrations of various stages in an example process flow for depositing nanotwinned copper on plated copper according to some implementations. In FIGS. 7A-7E, an example substrate 700 used for damascene processing is illustrated. In some implementations, the substrate 700 may be a semiconductor wafer, built on a semiconductor wafer, or part of a semiconductor wafer. A passivation layer 702 may be positioned over the substrate 700, where the passivation layer 702 may include an electrically insulating material such as silicon oxide (SiO₂) or silicon nitride (SiN). The passivation layer 702 may be patterned to define locations for electrically conductive interconnect structures 704. In some implementations, the electrically conductive interconnect structures 704 may include under bump metallization (UBM). Dielectric material may be formed over the passivation layer 702 and electrically conductive interconnect structures 704, where the dielectric material is patterned to form a patterned dielectric layer 706. The patterned dielectric layer 706 defines locations for copper vias/features in a copper damascene process. The patterned dielectric layer 706 may expose top surfaces of the electrically conductive interconnect structures 704. In FIGS. 7A-7E, a diffusion barrier layer and/or liner layer (not shown) may line the patterned dielectric layer 706.

In FIG. 7A, a copper seed layer 710 is deposited over the substrate 700. The copper seed layer 710 is ideally deposited conformally, following the surface topography with sufficiently thick uniformity along sidewalls and surfaces of the patterned dielectric layer 706 and at bottoms of recesses 712. In other words, the copper seed layer 710 is deposited in field regions outside recesses 712 and in recesses 712 covering an exposed interface with sufficient thickness uniformity to allow for plating on various exposed surfaces. The copper seed layer 710 is conformal and continuous along the patterned dielectric layer 706 and on top surfaces of the electrically conductive interconnect structures 704 in the recesses 712. The recesses 712 may be defined by the patterned dielectric layer 706. The recesses 712 are formed over the electrically conductive interconnect structures 704. In some implementations, the recesses 712 may have a high aspect ratio (depth-to-width aspect ratio). In some implementations, the aspect ratio of each of the recesses 712 may be equal to or greater than about 3:1, equal to or greater than about 4:1, equal to or greater than about 5:1, equal to or greater than about 8:1, equal to or greater than about 10:1, equal to or greater than about 15:1, equal to or greater than about 20:1, or equal to or greater than about 30:1.

In FIG. 7B, the recesses 712 are partially filled with copper to form plated copper features 720. The copper in the plated copper features 720 is non-nanotwinned copper. The copper is deposited by electroplating over the copper seed layer 710 in each of the recesses 712. The substrate 700 may be contacted with copper electroplating solution in an electroplating chamber, and the substrate 700 may be cathodically biased to electroplate copper on the copper seed layer 710. The copper electroplating solution may include organic additives such as accelerators to promote void-free bottom-up filling of the recesses 712. The recesses 712 are partially filled so that the plated copper features 720 do not reach a top surface of the patterned dielectric layer 706.

In FIG. 7C, the plated copper features 720 in the recesses 712 are exposed to a surface treatment 730. The surface treatment 730 may remove or render inactive contaminants and impurities such as accelerators from the top surface of the plated copper features 720. The surface treatment 730 may refine grain structures of the plated copper features 720 for promoting nanotwin growth. In some implementations, the surface treatment 730 includes an aqueous solution of a peroxide, sulfuric acid, dissolved ozone, or combinations thereof. In some implementations, the surface treatment 730 includes a solution containing electroplating leveling compounds. In some implementations, the chemical reagent includes compounds that are stable in a solution that contains a strong oxidizer that supports the solubility of oxidized copper ions. These include but are not limited to acids with soluble anions for copper (e.g., sulfuric acid, phosphoric acid, or hydrochloric acid), and copper ion complexing agents in higher pH solutions (e.g., EDTA, glycine, citrate, ethylene diamine). These generally should not include species that may strongly react with the copper surface (e.g., organo-mercapto compounds, BTA). In some implementations, the surface treatment 730 includes oxygen plasma. In some implementations, the surface treatment 730 includes ozone. In some implementations, the surface treatment 730 includes exposing the plated copper features 720 to thermal forming gas. In some implementations, the surface treatment 730 may include exposing the plated copper features to different solutions simultaneously or sequentially.

In FIG. 7D, nanotwinned copper 740 is electroplated on the plated copper features 720. The nanotwinned copper 740 fills the recesses 712. In some implementations, the nanotwinned copper 740 is plated in field regions outside the recesses 712, resulting in a copper overburden. The substrate 700 may be contacted with nanotwinned copper electroplating solution in an electroplating chamber, and the substrate 700 may be cathodically biased to electroplate nanotwinned copper 740 on the plated copper features 720. The nanotwinned copper electroplating solution is free or substantially free of accelerators. The nanotwinned copper 740 is electroplated under conditions that do not result in voids/seams. Furthermore, a transition region in the nanotwinned copper 740 is minimized, where an average thickness of the transition region is less than about 0.5 μm.

In FIG. 7E, a thermal anneal 750 is performed on the nanotwinned copper 740. The thermal anneal 750 may heat the nanotwinned copper 740 at a temperature between about 150° C. and about 400° C. or between about 250° C. and about 350° C. The thermal anneal 750 may further reduce a size of the transition region in the nanotwinned copper 740. In some implementations, the nanotwinned copper 740 may be planarized prior to the thermal anneal 750. The top surface of the patterned dielectric layer 706 may be exposed after planarization. In some implementations, the thermal anneal 750 may be applied for hybrid bonding or direct bonding interconnect applications.

The process flow in FIGS. 7A-7E may result in a damascene structure 760 of a semiconductor device 70. The damascene structure 760 may also be referred to as an electrically conductive interconnect structure of the semiconductor device 70. As shown in FIG. 7E, the semiconductor device 70 includes a substrate 700 and a patterned dielectric layer 706 over the substrate 700. The semiconductor device 70 further includes a damascene structure 760 over the substrate 70 and formed at least in the patterned dielectric layer 760, where the damascene structure 760 includes a plated copper feature 720 and nanotwinned copper 740 over the plated copper feature 720. The plated copper feature 720 is non-nanotwinned copper and occupies a base of the damascene structure 760. The nanotwinned copper 740 occupies an upper portion of the damascene structure 760. The plated copper feature 720 is formed at least partially in the patterned dielectric layer 706. In some implementations, the nanotwinned copper 740 occupies 30 vol. % or less of the damascene structure 760, 20 vol. % or less of the damascene structure 760, or 15 vol. % or less of the damascene structure 760. In some implementations, the plated copper feature 720 partially fills or completely fills recesses 712 of the patterned dielectric layer 706.

The plated copper feature 720 may include randomly-oriented copper grains and the nanotwinned copper 740 includes a plurality of nanotwins. The plated copper feature 720 and the nanotwinned copper 740 form a mixed crystal structure or hybrid crystal structure. The nanotwinned copper 740 may exhibit stronger mechanical properties and less film stress compared to the plated copper feature 720.

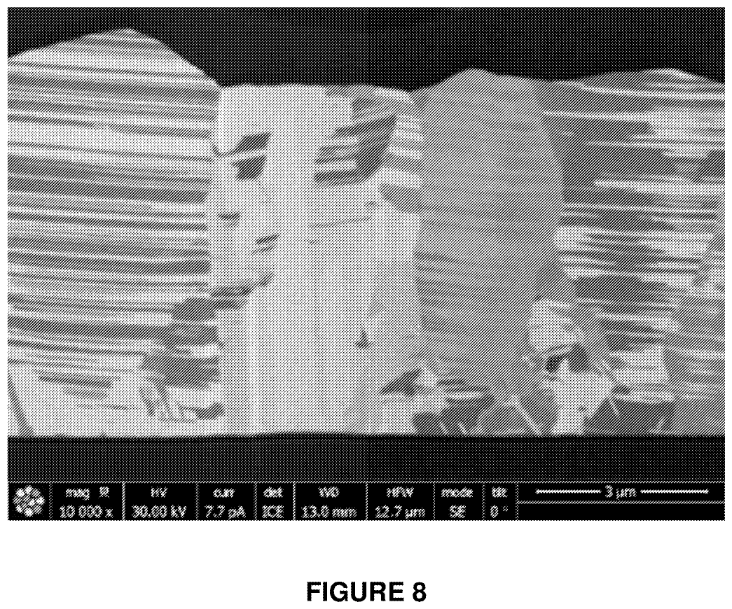

FIG. 8 shows a cross-sectional SEM image of a nanotwinned copper feature with a minimized transition region according to some implementations. The nanotwinned copper feature is grown on non-nanotwinned copper after a top surface of the non-nanotwinned copper is treated with a piranha etching solution. The surface treatment using the piranha etching solution on non-nanotwinned copper yields highly columnar grains and a high density of nanotwins in the nanotwinned copper feature. Moreover, the transition region in the nanotwinned copper feature is minimized so that a size of the transition region is negligible.

As discussed above, copper electroplating may proceed in a two-step manner with nanotwinned copper being plated on non-nanotwinned copper. The non-nanotwinned copper may partially or completely fill a recessed feature. In the present disclosure, copper electroplating may alternatively proceed in a two-step manner with non-nanotwinned copper being plated on nanotwinned copper. The nanotwinned copper may partially fill a recessed feature. Non-nanotwinned copper being plated on nanotwinned copper may form an electrically conductive interconnect structure such as a 2-in-1 copper via and RDL structure.

Forming electrically conductive vias, lines, pads, or other structures in semiconductor device fabrication often involves electroplating copper. Plated electrically conductive structures are often plated through patterned photoresist. An example of a plated electrically conductive structure includes copper RDL. Copper RDL is typically composed of polycrystalline copper. When plating copper RDL through patterned photoresist, the resulting copper may be deposited on a dielectric layer such as a polyimide layer. An interface between the plated copper and the dielectric layer may result in a significant mismatch of CTE (coefficient of thermal expansion). For instance, polycrystalline copper has a CTE of about 16.3 ppm/° C. and polyimide has a CTE of about 35 ppm/° C. Thermal cycling of the plated electrically conductive structure induces stress due to the CTE mismatch between the plated copper and the dielectric layer. This can lead to failure in the plated electrically conductive structure such as line cracking or delamination.

Nanotwinned copper generally has improved electrical and mechanical properties over non-nanotwinned copper such as polycrystalline copper. With better properties, nanotwinned copper is able to resist stresses induced from thermal cycling due to any CTE mismatch, thereby reducing the likelihood of cracking between plated copper and the dielectric layer. Plating nanotwinned copper instead of non-nanotwinned copper over dielectric layers to form electrically conductive structures may mitigate failures such as cracking.

Plating nanotwinned copper, however, is highly conformal. This is due in part to nanotwinned copper plating solutions being free or substantially free of accelerators. Incorporating nanotwinned copper in electrically conductive structures such as RDLs may present challenges since plating nanotwinned copper occurs according to a conformal fill mechanism. Conformal feature filling typically leads to the formation of seams or voids. Or, if the feature is only partially filled, significant dishing results that lead to topography issues in subsequent deposition, lithography, and/or other processing steps.

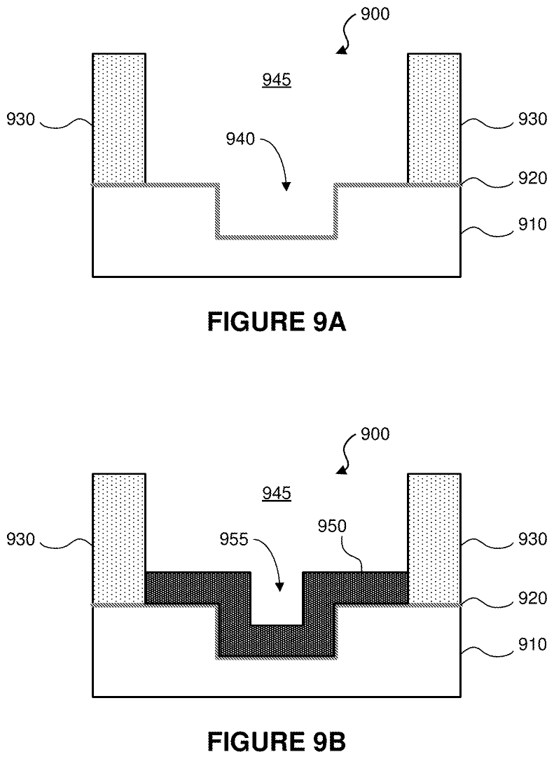

FIGS. 9A-9B show cross-sectional schematic illustrations of various stages in depositing nanotwinned copper in a 2-in-1 via and RDL. 2-in-1 vias and RDLs are often utilized in heterogeneous integration. 2-in-1 vias and RDLs are formed by simultaneously plating RDL lines and pads along with underlying vias.

In FIG. 9A, an example substrate 900 having a dielectric layer 910 is illustrated. The substrate 900 may be a semiconductor wafer, built on a semiconductor wafer, or part of a semiconductor wafer. In some implementations, the dielectric layer 910 may include an electrically insulating material such as polyimide. The dielectric layer 910 may be patterned to define locations for 2-in-1 features. In particular, the dielectric layer 910 may be patterned to define a recess or recessed feature 940. In some implementations, the recessed feature 940 may have sidewalls that are sloped, curved, or rounded. Photoresist is formed over the dielectric layer 910, where the photoresist is patterned to form a patterned photoresist 930. The patterned photoresist 930 defines a space or opening 945 through which copper is deposited to form a 2-in-1 via and RDL. In some implementations, a copper seed layer 920 is deposited over the dielectric layer 910. The copper seed layer 920 is deposited along sidewalls and a bottom of the recessed feature 940. The copper seed layer 920 is continuous and conformal along surfaces of the dielectric layer 910. In some implementations, an oxide layer and/or barrier layer (not shown) may be deposited on the dielectric layer 910.

In FIG. 9B, nanotwinned copper 950 is electroplated in the space or opening 945 defined by the patterned photoresist 930. The nanotwinned copper 950 is electroplated on the copper seed layer 920 over the dielectric layer 910. The nanotwinned copper 950 may form a 2-in-1 via and RDL defined by the patterned photoresist 930. The substrate 900 may be contacted with a nanotwinned copper electroplating solution in an electroplating chamber, and the substrate 900 may be cathodically biased to electroplate the nanotwinned copper 950 on the copper seed layer 920. The nanotwinned copper electroplating solution may be free or substantially free of accelerators. In some implementations, the nanotwinned copper electroplating solution may contain some organic additives such as suppressors. The nanotwinned copper 950 is deposited conformally in the recessed feature 940 and in areas adjacent to the recessed feature 940. Rather than filling the recessed feature 940 by bottom-up filling, the nanotwinned copper 950 partially fills the recessed feature 940. The partially filled feature results in a dimple 955 that may drive topological variations in subsequent processing steps. The dimple 955 may also be referred to as an indentation, dish, depression, divot, dip, gap, groove, or recess. The nanotwinned copper 950 deposited in the recessed feature 940 forms a copper via. The nanotwinned copper 950 deposited in areas adjacent to the recessed feature 940 and defined by the patterned photoresist 930 form copper RDLs. Topography is created by the 2-in-1 via and RDL when electroplating nanotwinned copper 950 because the nanotwinned copper 950 is plated conformally, thereby creating a copper via that dips to a lower depth than copper RDLs.

RDLs are interconnects that electrically connect one part of a semiconductor package to another. RDLs are often used in fan-out and 2.5-D or 3-D packaging. Advances in semiconductor packaging have necessitated more electrical interconnects and pathways. To meet the increased demand for more electrical interconnects and pathways, multiple RDL layers are often stacked on top of each other. Multiple RDL layers involve plural metallization layers and vias and plural dielectric (e.g., polymer) layers. One of the metallization layers is form on one of the dielectric layers, and another one of the dielectric layers is formed on the metallization layer, and so forth. Successive stacking of dielectric layers and metallization layers in a multilayer RDL structure can produce topographical discontinuities.

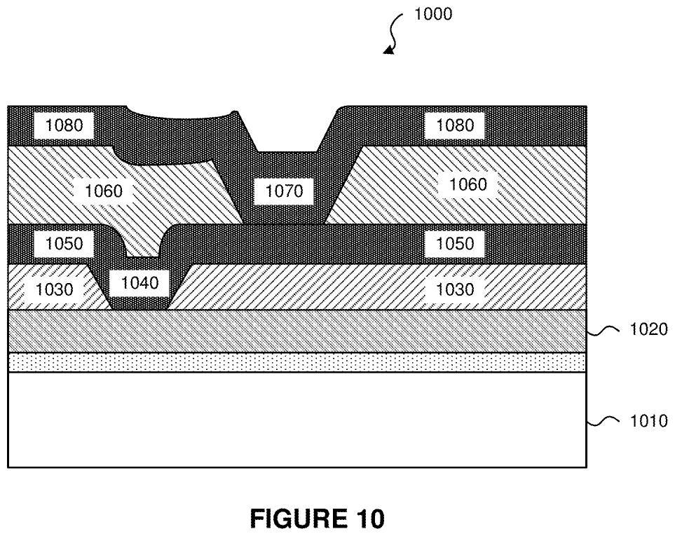

FIG. 10 shows a cross-sectional schematic illustration of a multilayer via and RDL structure with topographical variations resulting from conformally deposited nanotwinned copper. The multilayer via and RDL structure 1000 includes a substrate 1010 that may be a semiconductor wafer, built on a semiconductor wafer, or part of a semiconductor wafer. In some implementations, the substrate 1010 is a silicon substrate. A metal pad 1020 may be formed on the substrate 1010. In some implementations, the metal pad 1020 includes a metal such as copper, aluminum, tungsten, gold, silver, or alloys thereof. A first dielectric layer 1030 is disposed over the metal pad 1020. In some implementations, the first dielectric layer 1030 includes a polymer such as polyimide (PI) or polybenzoxazole (PBO). A first copper via 1040 may be formed in the first dielectric layer 1030 to electrically contact the metal pad 1020. In some implementations, a recess may be formed in the first dielectric layer 1030 using a photolithography process. Though not shown in FIG. 10, a diffusion barrier layer and/or liner layer may be deposited over the first dielectric layer 1030. In some cases, a barrier metal including titanium, tungsten, tantalum, or alloys thereof may line the first dielectric layer 1030. In some implementations, a copper seed layer (not shown) may be deposited over the barrier metal. The recess may be filled by electroplating nanotwinned copper. In addition, nanotwinned copper is electroplated in regions adjacent to the recess. This forms a first copper RDL 1050 over the first dielectric layer 1030, where the first copper RDL 1050 is formed simultaneous with the first copper via 1040 in a 2-in-1 fabrication scheme. Because the nanotwinned copper is conformally deposited in forming the first copper via 1040 and the first copper RDL 1050, a dimple can form in the first copper via 1040. Variation in depth occurs between the first copper via 1040 and the first copper RDL 1050. After formation of the first copper via 1040 and the copper RDL 1050, the process repeats. Photoresist may be removed. Optionally, any exposed barrier metal and the copper seed layer are removed. A second dielectric layer 1060 is disposed over the first copper via 1040 and the first copper RDL 1050. In some implementations, the second dielectric layer 1060 includes a polymer such as polyimide or polybenzoxazole. Because of the variation in depth from the first copper via 1040, successively deposited layers produce topological variations. Accordingly, portions of the second dielectric layer 1060 may be curved, rounded, dimpled, sloped, or otherwise uneven. A second copper via 1070 may be formed in the second dielectric layer 1060 to contact the first copper RDL 1050. In some implementations, a recess may be formed in the second dielectric 1060 using a photolithography process. The recess may be filled by electroplating nanotwinned copper. Furthermore, nanotwinned copper is electroplated in regions adjacent to the recess. This forms a second copper RDL 1080 over the second dielectric layer 1060, where the second copper RDL 1080 is formed simultaneous with the second copper via 1070 in a 2-in-1 fabrication scheme. Since the nanotwinned copper is conformally deposited in forming the second copper via 1070 and the second copper RDL 1080, a dimple can form in the second copper via 1070. Moreover, the topological variation in the second dielectric layer 1060 can induce topological discontinuities in the subsequently deposited second copper RDL 1080. These topological discontinuities lead to depth of focus (DOF) issues in subsequent photolithography steps. This in turn leads to line size variation across a surface of the substrate and resolution issues of finer line scaling. Problems associated with depth of focus and lack of uniform deposition increase as more and more copper RDLs are stacked. This can lead to poor device reliability, performance, and possible device failure.

The present disclosure provides nanotwinned copper in a 2-in-1 via and RDL structure while mitigating topological discontinuities. The 2-in-1 via and RDL structure also mitigates mechanical failures such as cracking by employing nanotwinned copper. Copper is electroplated in a two-step process that deposits a layer of nanotwinned copper over a dielectric layer. The layer of nanotwinned copper is electroplated in one or more recessed features of a substrate and in regions outside of the one or more recessed features defined by patterned photoresist. The regions outside the one or more recessed features may also be referred to as adjacent regions or regions adjacent to the recessed features. The layer of nanotwinned copper partially fills the one or more recessed features. The layer of nanotwinned copper is deposited to a target thickness for copper RDL lines in the regions outside of the one or more recessed features. Subsequent to deposition of the layer of nanotwinned copper, a layer of non-nanotwinned copper is electroplated over the layer of nanotwinned copper. The layer of non-nanotwinned copper fills the one or more recessed features to provide a copper via with the layer of nanotwinned copper. Thus, a filled recessed feature is formed of nanotwinned and non-nanotwinned copper without seams and/or voids and with little to no topological variations. In some implementations, a copper overburden is formed by deposition of the layer of non-nanotwinned copper. The copper overburden may represent excess non-nanotwinned copper in one or both of the regions defined by the copper via and defined by copper RDL lines. In some implementations, some or all of the copper overburden may be removed. In some implementations, the copper overburden may be removed by chemical etching. In some implementations, the copper overburden may be removed by CMP or electroplanarization.

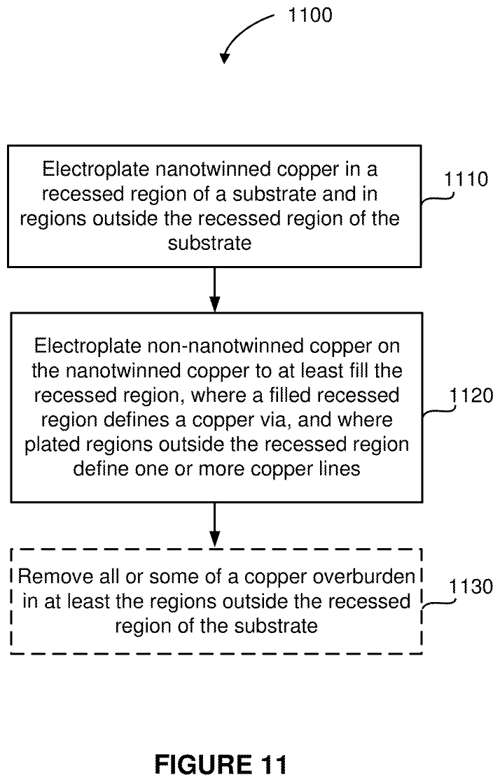

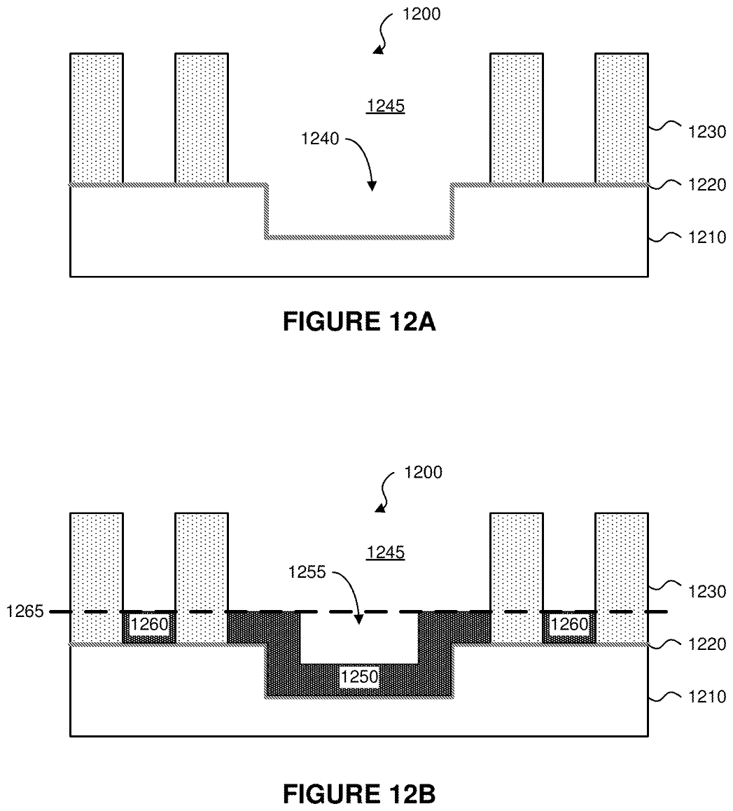

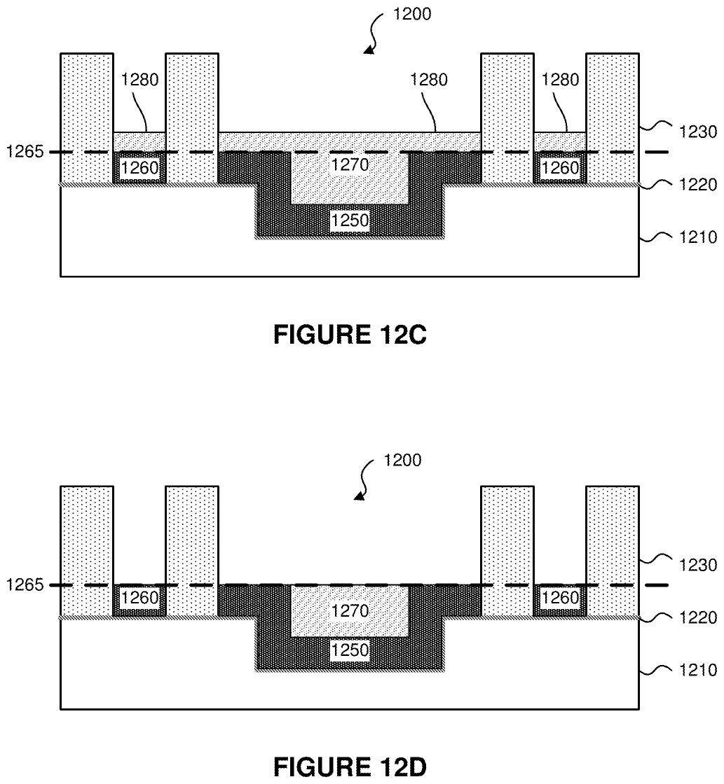

FIG. 11 shows a flow diagram of an example method of depositing a nanotwinned copper via and one or more nanotwinned copper lines according to some implementations. The operations in a process 1100 may be performed in different orders and/or with different, fewer, or additional operations. Aspects of the process 1100 may be described with reference to FIGS. 12A-12D. In some implementations, the operations in the process 1100 may be performed in an apparatus configured for electroplating. Electroplating nanotwinned copper and non-nanotwinned copper may be performed in the same tool platform or in the same module of a tool platform. Examples of electroplating apparatuses are described in FIGS. 13-15. One example of an electroplating apparatus is the Sabre® Electroplating System produced by and available from Lam Research Corporation of Fremont, Calif. In some implementations, the operations of the process 1100 may be implemented, at least in part, according to software stored in one or more non-transitory computer readable media.

At block 1110 of the process 1100, nanotwinned copper is electroplated in a recessed region of a substrate and in regions outside the recessed region of the substrate. In some implementations, the recessed region may be referred to as a “via” region and the regions outside the recessed region may be referred to as a “line” region for copper via and RDL structures. The nanotwinned copper may be electroplated over a dielectric layer of the substrate. The dielectric layer may include a polymer such as polyimide. The dielectric layer may be patterned with one or more recesses to form at least the recessed region of the substrate. Examples of recesses include but are not limited to trenches, holes, contact holes, openings, vias, gaps, cavities, and the like. In some implementations, the recessed region of the substrate can have straight sidewalls, curved sidewalls, positively sloped sidewalls, or negatively sloped sidewalls. In some implementations, the recessed region may have an aspect ratio of at least about 1:1, at least about 2:1, at least about 3:1, at least about 4:1, at least about 5:1, at least about 8:1, at least about 10:1, at least about 15:1, at least about 20:1, or at least about 30:1. In some implementations, the recessed region forms a recess through the dielectric layer to expose an underlying metal layer such as a metal pad.

In some implementations, a copper seed layer lines the recessed region and the regions outside the recessed region. The copper seed layer may be conformally deposited along a surface of the dielectric layer of the substrate. Additionally or alternatively, an adhesion layer, a diffusion barrier layer, a liner layer, and/or other material layer may line the surface of the dielectric layer. The copper seed layer or other material layer may line the sidewalls and bottom of the recessed region of the substrate as well as top surfaces of the substrate. Hence, the nanotwinned copper is electroplated directly on the copper seed layer or other material layer.

In some implementations, the regions outside the recessed region include a patterned photoresist layer. The nanotwinned copper is electroplated in the regions outside the recessed region defined by the patterned photoresist layer. In other words, the nanotwinned copper is electroplated on the substrate through the patterned photoresist layer. The nanotwinned copper may be selectively deposited on the copper seed layer and patterned according to the patterned photoresist layer.

The nanotwinned copper is conformally deposited in the recessed region and in the regions outside the recessed region. To electroplate nanotwinned copper, the surfaces of the substrate are contacted with a nanotwinned copper electroplating solution, and a first current is applied to the substrate to electroplate copper having a plurality of nanotwins. The first current may include a pulsed current waveform that alternates between a constant current and no current. The pulsed current waveform promotes the formation of (111)-oriented crystal copper grains and nanotwinning. The first current is applied when cathodically biasing the substrate while the nanotwinned copper electroplating solution is contacting the surfaces of the substrate. Aspects of the pulsed current waveform such as current density, duration of cycles, number of cycles, plating rate, etc. are described above for promoting nanotwinning in the nanotwinned copper. In some implementations, a second current is optionally applied to the substrate after the first current is applied, where a second current is a constant current waveform. This may occur while the nanotwinned copper electroplating solution is contacting the surfaces of the substrate. Aspects of the constant current waveform such as current density are described above for promoting the formation of the nanotwinned copper.

The nanotwinned copper is electroplated according to a conformal fill mechanism using the nanotwinned copper electroplating solution. The nanotwinned copper electroplating solution may include at least a source of copper and an acid. The nanotwinned copper electroplating solution may include one or more organic additives such as suppressors. However, the nanotwinned copper electroplating solution is free or substantially free of accelerators. In some implementations, the nanotwinned copper electroplating solution is also free or substantially free of levelers. The composition in the nanotwinned copper electroplating solution promotes the formation of nanotwinned copper during electroplating but may limit the fill mechanism to a conformal fill mechanism. Aspects of the nanotwinned copper electroplating solution such its composition and flow velocity are described above for promoting the formation of the nanotwinned copper.

The electroplated nanotwinned copper may form a layer of nanotwinned copper on the substrate. The layer of nanotwinned copper may partially fill the recessed region, where the layer of nanotwinned copper is deposited along sidewalls and a bottom of the recessed region. The layer of nanotwinned copper is deposited in the regions outside the recessed region defined by the patterned photoresist layer. These regions outside the recessed region of the substrate define the line regions. A thickness of the layer of nanotwinned copper may be a target thickness of one or more copper lines in the regions outside the recessed region. In addition, the thickness of the layer of nanotwinned copper may be a desired thickness associated with achieving a desired composition of nanotwinned copper in a copper via. Because the layer of nanotwinned copper is conformally deposited, the thickness of the layer of nanotwinned copper may the same or substantially the same in the recessed region and in the regions outside the recessed region. In some implementations, the thickness of the layer of nanotwinned copper is equal to or less than about 10 μm, equal to or less than about 5 μm, equal to or less than about 3 μm, or between about 0.5 μm and about 5 μm. In a 2-in-1 copper via and RDL structure, the layer of nanotwinned copper simultaneously forms a partially-filled copper via and copper lines.

In some implementations, prior to electroplating the nanotwinned copper, the substrate is optionally provided in an electroplating apparatus in the process 1100. The electroplating apparatus may include one or more plating modules. The substrate may be provided in one of the plating modules that is fluidly connected to a reservoir that can deliver the nanotwinned copper electroplating solution to the plating module. The incoming substrate may be processed and patterned prior to being provided in the electroplating apparatus. For example, the substrate may undergo operations of depositing the dielectric layer, patterning the dielectric layer to form the recessed region, depositing a copper seed layer, depositing photoresist material, and patterning the photoresist material to form the patterned photoresist layer, among other possible processing steps.

In some implementations, after electroplating the nanotwinned copper, the nanotwinned copper is optionally treated in the process 1100. In some implementations, the nanotwinned copper may be treated by a wet or dry treatment to remove contaminants or impurities.

In FIG. 12A, an example substrate 1200 used in 2-in-1 fabrication is illustrated. The substrate 1200 may be a semiconductor wafer, built on a semiconductor wafer, or part of a semiconductor wafer. In some implementations, the substrate 1200 is a silicon substrate. The substrate 1200 includes a dielectric layer 1210 that may include an electrically insulating material such as polyimide. The dielectric layer 1210 may be patterned to define locations for 2-in-1 features. The 2-in-1 features may be 2-in-1 via and RDL features. In some implementations, the dielectric layer 1210 may be patterned to define a recess or recessed feature 1240. In some implementations, the recessed feature 1240 may have sidewalls that are straight, sloped, curved, or rounded. A copper seed layer 1220 may be deposited over the dielectric layer 1210. The copper seed layer 1220 may be deposited along sidewalls and a bottom of the recessed feature 1240. The copper seed layer 1220 may be deposited along top surfaces of the dielectric layer 1210. The copper seed layer 1220 is continuous and conformal along surfaces of the dielectric layer 1210. In some implementations, an oxide layer and/or barrier layer (not shown) may be deposited on the dielectric layer 1210. Photoresist is also formed over the dielectric layer 1210, where the photoresist is patterned to form a patterned photoresist 1230. The patterned photoresist 1230 is formed over the copper seed layer 1210 in regions outside of the recessed feature 1240. The patterned photoresist 1230 defines a space or opening 1245 through which copper is deposited to form a 2-in-1 via and RDL.

In FIG. 12B, nanotwinned copper 1250 is deposited on the copper seed layer 1220 in the recessed feature 1240 to partially fill the recessed feature 1240, and nanotwinned copper 1260 is deposited in the regions outside the recessed feature 1240 defined by the patterned photoresist 1230. The nanotwinned copper 1250 in the recessed feature 1240 and the nanotwinned copper 1260 in the regions outside the recessed feature 1240 are deposited simultaneously by electroplating. The nanotwinned copper 1250 in the recessed feature 1240 can represent a partially fabricated copper via and the nanotwinned copper 1260 in the regions outside the recessed feature 1240 can represent one or more copper RDL lines. As shown in FIG. 12B, the nanotwinned copper 1260 in the regions outside the recessed feature 1240 is deposited to a target thickness 1265. In some implementations, the target thickness 1265 may be between about 0.5 μm and about 5 μm. The target thickness 1265 may represent a desired thickness for the one or more copper RDL lines. The nanotwinned copper 1250, 1260 is deposited conformally by electroplating, where the substrate 1200 is contacted with a nanotwinned copper electroplating solution in an electroplating chamber, and a pulsed current waveform may be applied to the substrate 1200 to electroplate copper with a plurality of nanotwins. The nanotwinned copper electroplating solution is free or substantially free of accelerators. In some implementations, the only organic additives in the nanotwinned copper electroplating solution may be suppressors. This promotes a conformal fill mechanism for deposition of the nanotwinned copper 1250, 1260.

Returning to FIG. 11, at block 1120 of the process 1100, non-nanotwinned copper is electroplated on the nanotwinned copper to at least fill the recessed region. The filled recessed region defines a copper via. This may also be referred to as “a nanotwinned copper via.” Plated regions outside the recessed region define one or more copper lines. This may also be referred to as “one or more nanotwinned copper lines” or “one or more nanotwinned copper RDL lines.” In some implementations, the non-nanotwinned copper includes polycrystalline copper. The non-nanotwinned copper fills any dimple, indentation, cavity, trench, or gap left in the recessed region after deposition of the nanotwinned copper. Deposition of the non-nanotwinned copper may proceed according to a bottom-up fill mechanism. This promotes formation of a copper via in the recessed region without seams and/or voids. It will be understood, however, that deposition of the non-nanotwinned copper may proceed according to other fill mechanisms. The non-nanotwinned copper may fill above height of the recessed region.

In some implementations, the non-nanotwinned copper is electroplated in the regions outside the recessed region of the substrate. A layer of non-nanotwinned copper may be deposited on the layer of nanotwinned copper in the regions outside the recessed region to define a copper overburden or at least portions of a copper overburden. The copper overburden may represent copper formed by excess filling of the recessed region. Non-nanotwinned copper in excess of filling the recessed region forms the copper overburden. The non-nanotwinned may laterally spread over the surface of the nanotwinned copper in addition to filling in recesses formed by the nanotwinned copper. Thus, the copper overburden may consist of non-nanotwinned copper deposited above a depth defined by a top surface of the nanotwinned copper in the regions outside the recessed region. In some implementations, a thickness of the copper overburden may be equal to or less than about 5 μm, equal to or less than about 3 μm, or between about 0.1 μm and about 3 μm. The non-nanotwinned copper may blanket the nanotwinned copper and form the copper overburden. Filling the recessed region with non-nanotwinned copper may result in undesirable topological variations in the copper via. Formation of a copper overburden followed by subsequent removal of the copper overburden may ensure increased planarity and reduced topological variations.

To electroplate the non-nanotwinned copper, the surfaces of the substrate are contacted with a copper electroplating solution, and the substrate is cathodically biased to fill the recessed region. The copper electroplating solution may simultaneously contact exposed surfaces of the nanotwinned copper while cathodically biasing the substrate. The copper electroplating solution includes at least a source of copper, an acid, and one or more organic additives to promote filling of the nanotwinned copper via. The copper electroplating solution may include at least one or more accelerators. In the present disclosure, the “nanotwinned copper via” or “copper via” constitutes a combination of nanotwinned copper and non-nanotwinned copper. The copper via may include a layer of non-nanotwinned copper such as polycrystalline copper deposited on a layer of nanotwinned copper. Nanotwinned copper may constitute at least 20 vol. %, at least 30 vol. %, or at least 40 vol. % of the copper via. The volume percent of nanotwinned copper in the copper via depends at least in part on the dimensions and target thickness of the copper lines, which is discussed in more detail below.

Electroplating non-nanotwinned copper at block 1120 may occur in the same electroplating apparatus as electroplating the nanotwinned copper at block 1110. In some implementations, the electroplating apparatus may include one or more plating modules, where each of the one or more plating modules are fluidly connected to two or more solution reservoirs or sources that can deliver different electroplating solutions to the electroplating apparatus. One of the solution reservoirs or sources can provide a nanotwinned copper electroplating solution. Another one of the solution reservoirs or sources can provide a non-nanotwinned copper electroplating solution (i.e., copper electroplating solution). In some implementations, the electroplating apparatus may be configured to provide the different electroplating solutions to a single plating module where the electroplating solutions are exchanged, though it will be understood that in other implementations the electroplating apparatus may be configured to provide the electroplating solutions to different plating modules. As such, one plating module may be configured to perform nanotwin plating at block 1110 (e.g., conformal plating), and another plating module may be configured to perform standard copper plating at block 1120 (e.g., filling).

In some implementations, electroplating nanotwinned copper and electroplating non-nanotwinned copper may be performed without introducing a vacuum break in between operations. In a direct process flow, a plating module performs nanotwin plating and transfers the substrate to another plating module to perform standard copper plating in the same electroplating tool or apparatus. This can occur in a single pass. In a sequential process flow, a plating module performs nanotwin plating and transfers the substrate via transfer stations, cassettes, or spin rinse drying stations to another module to perform standard copper plating. The transfer may occur within the same electroplating tool or between different electroplating tools.

In FIG. 12C, the recessed feature 1240 is filled with non-nanotwinned copper 1270. Non-nanotwinned copper 1270 is deposited by electroplating on the nanotwinned copper 1250. The substrate 1200 is contacted with copper electroplating solution in an electroplating chamber, and the substrate 1200 may be cathodically biased to electroplate non-nanotwinned copper 1270 on the nanotwinned copper 1250. The copper electroplating solution contains organic additives such as accelerators, which may promote bottom-up filling in the recessed feature 1240. The recessed feature 1240 is filled without seams or voids. The non-nanotwinned copper 1270 fills the recessed feature 1240 to at least a depth defined by a target thickness 1265. As shown in FIG. 12C, the non-nanotwinned copper 1270 fills above the depth defined by the target thickness 1265 to form a copper overburden 1280. Accordingly, the copper overburden 1280 is deposited on the nanotwinned copper 1260 in the regions outside the recessed feature 1240. The copper overburden 1280 may blanket the nanotwinned copper 1250 in the recessed feature 1240 and the nanotwinned copper 1260 in the regions outside the recessed feature 1240.

Returning to FIG. 11, at block 1130 of the process 1100, all or some of a copper overburden is optionally removed in at least regions outside the recessed region of the substrate. Where a copper overburden is formed over the nanotwinned copper in the regions outside of the recessed region, at least some of the copper overburden is removed. Removal of at least some of the copper overburden may planarize the surface of the copper via and the one or more copper lines, thereby reducing nonuniformities on the surfaces of the copper via and the one or more copper lines. Removal of some or all of the copper overburden may also achieve a desired amount of nanotwinned copper in the copper via and the one or more copper lines. In some implementations, at least a substantial fraction of the copper overburden is removed so that the one or more copper lines are composed of at least 50 vol. % nanotwinned copper, at least 75 vol. % nanotwinned copper, or at least 90 vol. % nanotwinned copper. As used herein, a “substantial fraction” of the copper overburden for removal may constitute at least 50 vol. % of the copper overburden. Generally, it is desirable to remove as much of the copper overburden as possible to maximize the amount of nanotwinned copper in copper lines. In some cases, however, it may be desirable to optimize throughput and remove only a small fraction of the copper overburden, where a “small fraction” of the copper overburden for removal may constitute less than 50 vol. % of the copper overburden. To further optimize throughput in some instances, no copper overburden is removed in the copper lines.

A sufficient amount of the copper overburden is removed to achieve a target thickness of the one or more copper lines. In some implementations, all of the copper overburden is removed so that the target thickness is the thickness of the nanotwinned copper in the regions outside the recessed region. The nanotwinned copper in the regions outside the recessed region define the one or more copper lines, and the non-nanotwinned copper and the nanotwinned copper in the recessed region define the copper via. In some other implementations, some of the copper overburden is removed so that any remaining non-nanotwinned copper and nanotwinned copper in the regions outside the recessed region define the one or more copper lines, and any remaining non-nanotwinned copper and nanotwinned copper in the recessed region define the copper via. In such cases, the target thickness is the total thickness of the nanotwinned copper and the non-nanotwinned copper in the regions outside the recessed region after partial removal of the copper overburden. The target thickness may be less than a height of the patterned photoresist layer.

In some implementations, removal of the copper overburden may be accomplished by a chemical etch, electroplanarization, or chemical mechanical planarization (CMP). For example, some or all of the copper overburden may be removed by a chemical etch. The chemical etch may eliminate or otherwise reduce surface topography and produce a planar surface. The chemical etch may be an isotropic chemical etch. In some implementations, the chemical etch is selective to copper. That way, the chemical etch selectively removes some or all of the copper overburden relative to surrounding materials. In some implementations, the chemical etch uses an etching solution that includes at least an oxidizing agent. The oxidizing agent in the etching solution serves to at least convert copper to copper oxide. Examples of oxidizing agents include dilute aqueous solutions of peroxides (such as hydrogen peroxide), persulfates, ozone, and/or permanganates. In some implementations, copper oxide is exposed to an oxide etching agent to remove the copper oxide. Examples of oxide etching agents include but are not limited to dilute acids, glycine, and various copper complexing agents. Suitable complexing agents may include ethylenediamine tetraacetic acid (EDTA), citric acid and salts thereof, and maleic acid and salts thereof. The oxidizing agent and the oxide etching agent may be parts of the same solution. Or, the oxidizing agent and the oxide etching agent may be separate solutions. In some implementations, the chemical etch uses an etching solution that directly etches the copper without forming copper oxide. Such an etching solution may be a relatively high pH solution such as a solution of tetramethyl ammonium hydroxide, ethanol amine, ammonium hydroxide, and the like. In either the etching solution with the oxidizing agent or without the oxidizing agent, a corrosion inhibitor and/or surfactant may be incorporated to modulate etch rate. In some other implementations, the chemical etch uses an oxidizing gas to at least convert copper to copper oxide. Exposure to oxidizing gas may be followed by exposure to an aqueous solution of an oxide etching agent to remove the copper oxide. The chemical etch does not significantly roughen the surface of the copper that would otherwise create pits or cavities deep enough to retain pockets of moisture during subsequent processing operations. Aspects of the chemical etch are described in detail in U.S. Pat. No. 7,972,970 to Mayer et al., entitled “FABRICATION OF SEMICONDUCTOR INTERCONNECT STRUCTURE,” which is incorporated herein by reference in its entirety and for all purposes.

Alternatively, some or all of the copper overburden may be removed by electroplanarization. Electroplanarization may describe a process of electroetching and electropolishing. Electroplanarization may be used interchangeably with the terms “electrochemical etch-back,” “electroetching,” “electropolishing,” “electrochemical metal removal,” and “electrochemical metal dissolution.” Electroplanarization generally involves contacting a working surface of a substrate having an exposed copper layer with an electrolyte and anodically biasing the substrate so that copper is electrochemically dissolved in the electrolyte. Alternatively, some or all of the copper overburden may be removed by CMP. A mechanical pad, physical contact with solid polishing instruments, and/or abrasive slurry can be used for CMP for copper removal and uniformity improvement.

The foregoing techniques applied to the copper overburden may serve to smooth out a top surface of the one or more copper lines. This would otherwise lead to topography issues in subsequent processing steps. In some implementations, a chemical isotropic etch may smooth out the one or more copper lines and act as a “brightener” without having to resort to a more costly CMP step.

In FIG. 12D, the copper overburden 1280 is removed. The copper overburden 1280 may be removed using any suitable removal technique such as CMP, electroplanarization, or chemical etch. For instance, the copper overburden 1280 may be removed by a selective and isotropic chemical etch. As shown in FIG. 12D, the copper overburden 1280 is removed to the target thickness 1265. That way, the non-nanotwinned copper 1270 is formed over the nanotwinned copper 1250 in the recessed feature 1240 but not disposed over the nanotwinned copper 1260 in the regions outside the recessed feature 1240. Copper RDL lines may be defined by the nanotwinned copper 1260 in the regions outside the recessed feature 1240, and a copper via may be defined by the combination of the nanotwinned copper 1250 and the non-nanotwinned copper 1270 in the recessed feature 1240. Thus, a semiconductor device may include a substrate 1200 with a dielectric layer 1210, where the copper via is formed in the dielectric layer 1210 having the combination of a layer of nanotwinned copper 1250 and a layer of non-nanotwinned copper 1270 formed over the layer of nanotwinned copper 1250, and where the one or more copper RDL lines formed over the dielectric layer 1210 is composed of a layer of nanotwinned copper 1260 or composed substantially of the layer of nanotwinned copper 1260. Composed “substantially” of nanotwinned copper may refer to copper RDL lines including at least 50 vol. % nanotwinned copper. The non-nanotwinned copper 1270 fills the recessed feature 1240 that is formed in the dielectric layer 1210. The non-nanotwinned copper 1270 may include randomly-oriented copper grains and the layer of nanotwinned copper 1250, 1260 may include a plurality of nanotwins. The non-nanotwinned copper 1270 combined with the layer of nanotwinned copper 1250, 1260 form a mixed crystal structure or hybrid crystal structure. The layer of nanotwinned copper 1250, 1260 may exhibit stronger mechanical properties and less film stress compared to the non-nanotwinned copper 1270.

Returning to FIG. 11, the process 1100 may proceed with removal of patterned photoresist layer in some implementations. The patterned photoresist layer may be removed by stripping. After removal of the patterned photoresist layer, any exposed barrier metal and/or seed layer can be removed. The copper via and the one or more copper lines may be treated after removal of the patterned photoresist layer. In some implementations, the copper via and the one or more copper lines may undergo thermal anneal. Annealing nanotwinned copper in the copper via and the one or more copper lines may eliminate or reduce a size of a transition region in the nanotwinned copper. In some implementations, an annealing temperature is between about 100° C. and about 400° C. or between about 150° C. and about 300° C., such as about 250° C. Annealing may be performed for a duration between about 1 minute and about 5 hours, between about 5 minutes and about 3 hours, or between about 10 minutes and about 2 hours. In some implementations, the process 1100 may proceed with formation of a multilayer via and RDL structure as described in FIG. 10. Unlike FIG. 10, however, the addition of non-nanotwinned copper on nanotwinned copper in forming copper vias and RDLs reduces topological variations in the multilayer via and RDL structure. The presence of nanotwinned copper in the copper vias and RDLs reduces any effects caused by CTE mismatch.

### Apparatus

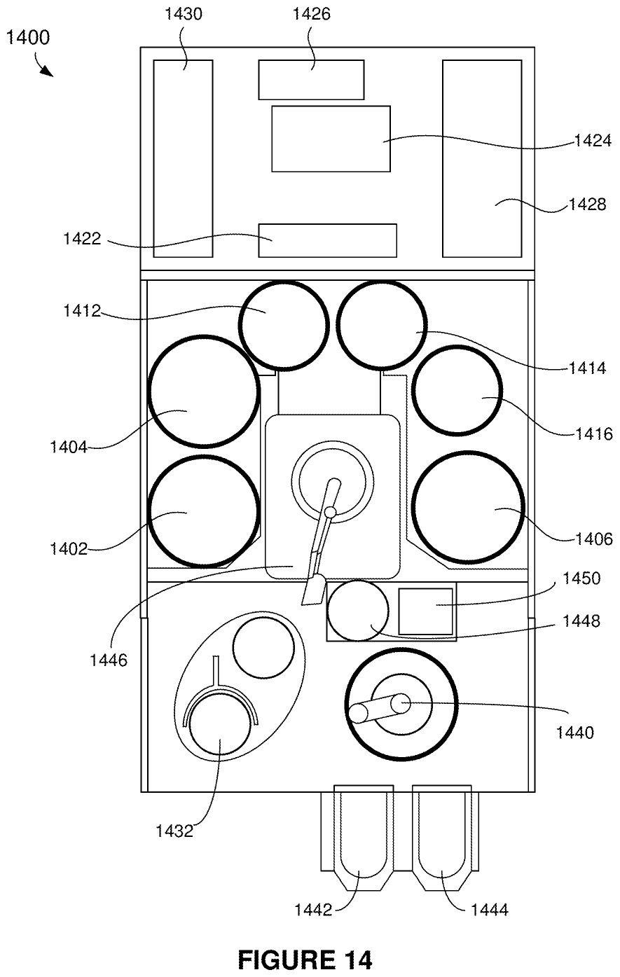

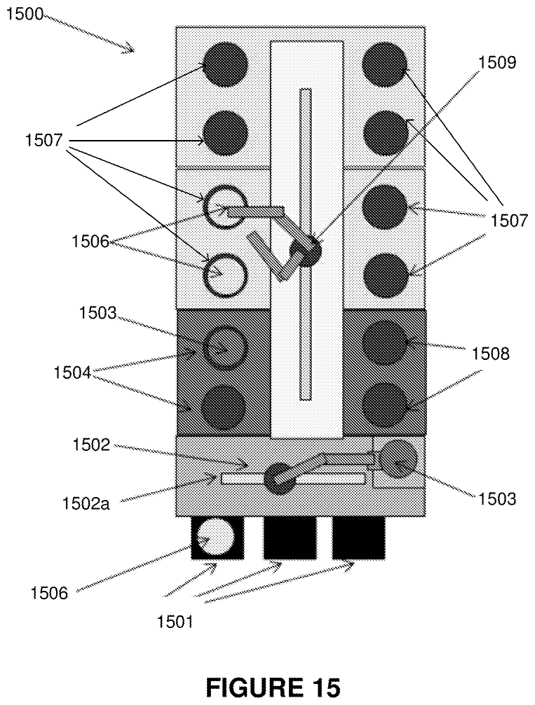

Many apparatus configurations may be used in accordance with the implementations described herein. Electroplating operations as described in the present disclosure may be performed in an electroplating cell of an electroplating apparatus as shown in FIG. 13. Surface treatment operations as described in the present disclosure may be performed in the electroplating cell of the electroplating apparatus, a spin-rinse-drying chamber of the electroplating apparatus, or treatment chamber of the electroplating apparatus. It will be appreciated that electroplating operations and surface treatment operations may be integrated within the same tool platform, which is demonstrated in FIGS. 14 and 15.

FIG. 13 shows a schematic diagram of an example of an electroplating cell in which electroplating may occur according to some implementations. Often, an electroplating apparatus includes one or more electroplating cells in which the substrates (e.g., wafers) are processed. Only one electroplating cell is shown in FIG. 13 to preserve clarity. To optimize bottom-up electroplating, additives may be added to the electroplating solution; however, an electroplating solution with accelerators may inhibit growth of nanotwins in copper structures.

An implementation of an electroplating apparatus 1301 is shown in FIG. 13. A plating bath 1303 contains the electroplating solution (having a composition as discussed herein), which is shown at a level 1305. A substrate 1307 is immersed into the electroplating solution and is held by, e.g., a “clamshell” substrate holder 1309, mounted on a rotatable spindle 1311, which allows rotation of clamshell substrate holder 1309 together with the substrate 1307. A general description of a clamshell-type plating apparatus having aspects suitable for use with this invention is described in detail in U.S. Pat. No. 6,156,167 issued to Patton et al., and U.S. Pat. No. 6,800,187 issued to Reid et al., which are incorporated by reference in their entireties and for all purposes.

An anode 1313 is disposed below the substrate 1307 within the plating bath 1303 and is separated from the substrate region by a membrane 1315, preferably an ion selective membrane. For example, Nafion™ cationic exchange membrane (CEM) may be used. The region below the anodic membrane is often referred to as an “anode chamber.” The ion-selective anode membrane 1315 allows ionic communication between the anodic and cathodic regions of the plating cell, while preventing the particles generated at the anode from entering the proximity of the substrate 1307 and contaminating it. The anode membrane is also useful in redistributing current flow during the plating process and thereby improving the plating uniformity. Detailed descriptions of suitable anodic membranes are provided in U.S. Pat. Nos. 6,126,798 and 6,569,299 issued to Reid et al., both incorporated by reference in their entireties and for all purposes. Ion exchange membranes, such as cationic exchange membranes, are especially suitable for these applications. These membranes are typically made of ionomeric materials, such as perfluorinated co-polymers containing sulfonic groups (e.g. Nafion™), sulfonated polyimides, and other materials known to those of skill in the art to be suitable for cation exchange. Selected examples of suitable Nafion™ membranes include N324 and N424 membranes available from Dupont de Nemours Co.

During plating, the ions from the electroplating solution are deposited on the substrate 1307. The copper ions must diffuse through the diffusion boundary layer and into the TSV hole or other feature. A typical way to assist the diffusion is through convection flow of the electroplating solution provided by a pump 1317. Additionally, a vibration agitation or sonic agitation member may be used as well as substrate rotation. For example, a vibration transducer 1308 may be attached to the clamshell substrate holder 1309.

The electroplating solution is continuously provided to plating bath 1303 by the pump 1317. Generally, the electroplating solution flows upwards through an anode membrane 1315 and a diffuser plate 1319 to the center of substrate 1307 and then radially outward and across substrate 1307. The electroplating solution also may be provided into the anodic region of the bath from the side of the plating bath 1303. The electroplating solution then overflows plating bath 1303 to an overflow reservoir 1321. The electroplating solution is then filtered (not shown) and returned to pump 1317 completing the recirculation of the electroplating solution. In certain configurations of the plating cell, a distinct electrolyte is circulated through the portion of the plating cell in which the anode is contained while mixing with the main electroplating solution is prevented using sparingly permeable membranes or ion selective membranes.

A reference electrode 1331 is located on the outside of the plating bath 1303 in a separate chamber 1333, which chamber is replenished by overflow from the main plating bath 1303. Alternatively, in some implementations, the reference electrode 1331 is positioned as close to the substrate surface as possible, and the reference electrode chamber is connected via a capillary tube or by another method, to the side of the substrate 1307 or directly under the substrate 1307. In some implementations, the electroplating apparatus 1301 further includes contact sense leads that connect to the substrate periphery and which are configured to sense the potential of the copper seed layer at the periphery of the substrate 1307 but do not carry any current to the substrate 1307.

A DC power supply 1335 can be used to control current flow to the substrate 1307. The power supply 1335 has a negative output lead 1339 electrically connected to substrate 1307 through one or more slip rings, brushes and contacts (not shown). The positive output lead 1341 of power supply 1335 is electrically connected to an anode 1313 located in plating bath 1303. The power supply 1335, a reference electrode 1331, and a contact sense lead (not shown) can be connected to a system controller 1347, which allows, among other functions, modulation of current and potential provided to the elements of electroplating cell. For example, the controller 1347 may allow electroplating in potential-controlled and current-controlled regimes. The controller 1347 may include program instructions specifying current and voltage levels that need to be applied to various elements of the plating cell, as well as times at which these levels need to be changed. When forward current is applied, the power supply 1335 biases the substrate 1307 to have a negative potential relative to anode 1313. This causes an electrical current to flow from anode 1313 to the substrate 1307, and an electrochemical reduction (e.g. Cu²⁺+2 e⁻=Cu⁰) occurs on the substrate surface (the cathode), which results in the deposition of the electrically conductive layer (e.g. copper) on the surfaces of the substrate 1307. An inert anode 1314 may be installed below the substrate 1307 within the plating bath 1303 and separated from the substrate region by the membrane 1315.

The electroplating apparatus 1301 may also include a heater 1345 for maintaining the temperature of the electroplating solution at a specific level. The electroplating solution may be used to transfer the heat to the other elements of the plating bath 1303. For example, when a substrate 1307 is loaded into the plating bath 1303, the heater 1345 and the pump 1317 may be turned on to circulate the electroplating solution through the electroplating apparatus 1301, until the temperature throughout the electroplating apparatus 1301 becomes substantially uniform. In some implementations, the heater 1345 is connected to the system controller 1347. The system controller 1347 may be connected to a thermocouple to receive feedback of the electroplating solution temperature within the electroplating apparatus 1301 and determine the need for additional heating.

The electrodeposition methods disclosed herein can be described in reference to, and may be employed in the context of, various electroplating tool apparatuses. One example of a plating apparatus that may be used according to the embodiments herein is the Lam Research Sabre® tool. Electroplating of non-nanotwinned copper, electroplating of nanotwinned copper, surface treatment of non-nanotwinned copper, and other methods disclosed herein can be performed in components that form a larger electroplating apparatus.

FIG. 14 shows a schematic of a top view of an example integrated system for performing electroplating and surface treatment according to some implementations. As shown in FIG. 14, the integrated system 1400 may include multiple electroplating modules, in this case the three separate modules 1402, 1404, and 1406. Each electroplating module typically includes a cell for containing an anode and an electroplating solution during electroplating, and a substrate holder for holding the substrate in the electroplating solution and rotating the substrate during electroplating. In some implementations, one of the electroplating modules 1402, 1404, and 1406 may be configured for non-nanotwinned copper electroplating and another one of the electroplating modules 1402, 1404, and 1406 may be configured for nanotwinned electroplating. The electroplating system 1400 can also include three separate modules 1412, 1414, and 1416 configured for various process operations. In some implementations, one or more of modules 1412, 1414, and 1416 may be a spin rinse drying (SRD) module. The SRD module may be configured to perform a planarization process such as a chemical etch for removing copper overburden. In some implementations, one or more of modules 1412, 1414, and 1416 may be a removal module for removing copper overburden. In one example, the removal module may be configured to provide one or more etching solutions for performing an isotropic chemical etch to remove copper overburden. In another example, the removal module may be configured to perform an electroplanarization process to remove copper overburden. In some implementations, one or more of the modules 1412, 1414, and 1416 may be a surface treatment module. The surface treatment module may be configured to supply an oxidizing agent or other chemical reagent for surface treatment of non-nanotwinned copper. In one example, the oxidizing agent is peroxide (e.g., hydrogen peroxide or permanganate), sulfuric acid, dissolved ozone, or combinations thereof. In another example, the chemical reagent is a solution containing one or more electroplating leveling compounds. In another example, the oxidizing agent is oxygen plasma. In yet another example, the oxidizing agent is ozone. In another example, the chemical reagent is forming gas provided at an elevated temperature. It will be understood that in some implementations, the spin rinse drying module may be configured to supply the oxidizing agent or other chemical reagent for surface treatment of non-nanotwinned copper.

The integrated system 1400 may also include a central electrolyte bath 1424 configured to hold electrolyte that is used for electroplating. The central electrolyte bath 1424 may be a tank that holds the chemical solution used as the electrolyte in the electroplating modules 1402, 1404, and 1406. The integrated system 1400 may also include a dosing system 1426 that may store and deliver additives for the electroplating solution. A chemical dilution module 1422 may store and mix chemicals. In some implementations, a filtration and pumping unit 1428 filters the electrolyte solution for central electrolyte bath 1424 and pumps it to the electroplating modules 1402, 1404, and 1406. However, it will be understood that each electroplating module 1402, 1404, and 1406 may include their own dosing module for adding additives to the electroplating solution, their own filtration and pumping unit, and their own electrolyte bath.

In some implementations of the integrated system 1400, a single electroplating module 1402/1404/1406 may be configured to perform multiple electroplating operations and/or surface treatment operations. For instance, the electroplating module 1402/1404/1406 may be fluidically connected to two or more solution reservoirs that can inject different solutions into the electroplating module 1402/1404/1406. Non-nanotwinned copper may be deposited using a non-nanotwinned copper electroplating solution, surface treatment may be applied using a wet treatment solution (e.g., piranha etching solution, solution with electroplating leveling compounds, etc.), and nanotwinned copper may be deposited suing a nanotwinned electroplating solution. Various hardware and processes are run in the single electroplating module 1402/1404/1406 where the plating and/or wet treatment solutions are exchanged, power turned off between operations, etc., but the substrate is not changed in between operations.

A system controller 1430 provides electronic and interface controls required to operate the integrated system 1400. The system controller 1430 (which may include one or more physical or logical controllers) controls some or all of the properties of the integrated system 1400. The system controller 1430 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 1430 or they may be provided over a network. In certain embodiments, the system controller 1430 executes system control software.

The system control software in the integrated system 1400 may include instructions for controlling the timing, mixture of electrolyte components (including the concentration of one or more electrolyte components), oxidizing agent/chemical reagent composition, inlet pressure, plating cell pressure, plating cell temperature, substrate temperature, current and potential applied to the substrate and any other electrodes, substrate position, substrate rotation, and other parameters of a particular process performed by the integrated system 1400. The system control logic may also include instructions for electroplating under conditions that are tailored to be appropriate for depositing nanotwinned copper structures or non-nanotwinned copper structures. For example, the system control logic may be configured with instructions to provide a constant current waveform with an electrolyte containing accelerators for deposition of non-nanotwinned copper, provide an oxidizing agent or other chemical reagent to treat the non-nanotwinned copper, and provide a pulsed current waveform with an electrolyte without accelerators for deposition of nanotwinned copper. The system control logic may be configured with instructions to provide the electrolyte without accelerators to the substrate at a relatively low flow rate for deposition of the nanotwinned copper. The system control logic may be configured with instructions for providing a wet treatment solution or dry treatment gas/plasma for removing or rendering inactive contaminants from the non-nanotwinned copper. The system control logic may be configured with instructions for annealing the nanotwinned copper. The system control logic may be configured with instructions for removing excess non-nanotwinned copper in a copper overburden. System control logic may be configured in any suitable way. For example, various process tool component sub-routines or control objects may be written to control operation of the process tool components necessary to carry out various process tool processes. System control software may be coded in any suitable computer readable programming language. The logic may also be implemented as hardware in a programmable logic device (e.g., an FPGA), an ASIC, or other appropriate vehicle.

In some implementations, system control logic includes input/output control (IOC) sequencing instructions for controlling the various parameters described above. For example, each phase of an electroplating, surface treatment, and/or annealing process may include one or more instructions for execution by the system controller 1430. The instructions for setting process conditions for an immersion process phase may be included in a corresponding immersion recipe phase. In some implementations, the electroplating, surface treatment, overburden removal, and/or annealing recipe phases may be sequentially arranged, so that all instructions for the electroplating, surface treatment, overburden removal, and/or annealing process phase are executed concurrently with that process phase.

The control logic may be divided into various components such as programs or sections of programs in some implementations. Examples of logic components for this purpose include a substrate positioning component, an electrolyte composition control component, a surface treatment composition component, a pressure control component, a heater control component, and a potential/current power supply control component.

In some implementations, there may be a user interface associated with the system controller 1430. The user interface may include a display screen, graphical software displays of the apparatus and/or process conditions, and user input devices such as pointing devices, keyboards, touch screens, microphones, etc.

In some implementations, parameters adjusted by the system controller 1430 may relate to process conditions. Non-limiting examples include bath conditions (temperature, composition, and flow rate), substrate position (rotation rate, linear (vertical) speed, angle from horizontal) at various stages, etc. These parameters may be provided to the user in the form of a recipe, which may be entered utilizing the user interface.

Signals for monitoring the process may be provided by analog and/or digital input connections of the system controller 1430 from various process tool sensors. The signals for controlling the process may be output on the analog and digital output connections of the process tool. Non-limiting examples of process tool sensors that may be monitored include mass flow controllers, pressure sensors (such as manometers), thermocouples, optical position sensors, etc. Appropriately programmed feedback and control algorithms may be used with data from these sensors to maintain process conditions.

In some implementations, the system controller 1430 may be configured with program instructions for performing the following operations: electroplating a copper feature on a substrate in an electroplating chamber such as an electroplating module 1402, exposing a surface of the copper feature to an oxidizing agent or other chemical reagent to treat the copper feature, and electroplating nanotwinned copper on the copper feature in a nanotwinned electroplating chamber such as an electroplating module 1404. In some implementations, each of the electroplating modules 1402, 1404 may be fluidically connected to a particular solution reservoir. The copper feature may comprise non-nanotwinned copper. In some implementations, exposing the surface of the copper feature with the oxidizing agent or other chemical reagent occurs in the electroplating module 1402 as a post-treatment operation. In some implementations, exposing the surface of the copper feature with the oxidizing agent or other chemical reagent occurs in the electroplating module 1404 as a pre-treatment operation. In some implementations, a spin rinse drying module 1414 is configured to hold the oxidizing agent or other chemical reagent, where exposing the surface of the copper feature occurs in the spin rinse drying module 1414. In some implementations, a treatment module 1412 is configured to hold the oxidizing agent or other chemical reagent, where exposing the surface of the copper feature occurs in the treatment module 1412. In some implementations, each of the operations of electroplating a copper feature on a substrate, exposing a surface of the copper feature to an oxidizing agent or other chemical reagent to treat the copper feature, and electroplating nanotwinned copper on the copper feature is performed in an electroplating module 1402, where the electroplating module 1402 may be fluidically connected to two or more solution reservoirs. The substrate is not transferred in between operations.

In some implementations, the system controller 1430 may be configured with program instructions for performing the following operations: electroplate nanotwinned copper in a recessed region of a substrate and in regions outside the recessed region of the substrate in an electroplating chamber such as an electroplating module 1402, and electroplate non-nanotwinned copper on the nanotwinned copper to at least fill the recessed region in an electroplating chamber such as an electroplating module 1404, where the filled recessed region defines a copper via and where the plated regions outside the recessed region define one or more copper lines. In some implementations, each of the electroplating modules 1402, 1404 may be fluidically connected to a particular solution reservoir. In some implementations, excess non-nanotwinned copper that form a copper overburden may be removed in a removal module 1416 or spin rinse drying module 1414. The removal module 1416 may be configured to hold an etching solution. In some instances, the etching solution may contain an oxidizing agent and/or oxide etching agent. In some implementations, each of the operations of electroplating the nanotwinned copper and electroplating the non-nanotwinned copper is performed in an electroplating module 1402, where the electroplating module 1402 may be fluidically connected to two or more solution reservoirs. The substrate is not transferred in between operations.

A hand-off tool 1440 may select a substrate from a substrate cassette such as the cassette 1442 or the cassette 1444. The cassettes 1442 or 1444 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 1440 may hold the substrate using a vacuum attachment or some other attaching mechanism.

The hand-off tool 1440 may interface with a substrate handling station 1432, the cassettes 1442 or 1444, a transfer station 1450, or an aligner 1448. From the transfer station 1450, a hand-off tool 1446 may gain access to the substrate. The transfer station 1450 may be a slot or a position from and to which hand-off tools 1440 and 1446 may pass substrates without going through the aligner 1448. In some implementations, however, to ensure that a substrate is properly aligned on the hand-off tool 1446 for precision delivery to an electroplating module or surface treatment module, the hand-off tool 1446 may align the substrate with an aligner 1448. The hand-off tool 1446 may also deliver a substrate to one of the electroplating modules 1402, 1404, or 1406, to one of the surface treatment modules 1412, 1414, and 1416, or to one of the removal modules 1412, 1414, or 1416 configured for various process operations.

In some implementations, a controller (e.g., system controller 1430) is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of electroplating solution, electrolyte solution, temperature settings (e.g., heating and/or cooling), pressure settings, power settings, current waveform settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of WLP features of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In an example operation of the integrated system 1400, the hand-off tool 1440 selects a substrate from cassette 1442 or cassette 1444. From a transfer station 1450, the hand-off tool 1446 gains access to the substrate and transfers the substrate to a treatment module 1412. The treatment module 1412 is configured to treat a surface of the substrate with an oxidizing agent or other chemical reagent described in the present disclosure. The hand-off tool 1446 may transfer the substrate from the treatment module 1412 to an electroplating module 1402. The electroplating module 1402 may be configured to electroplate nanotwinned copper on the substrate using a nanotwinned copper electroplating solution. In some implementations, the hand-off tool 1446 may transfer the substrate from the electroplating module 1402 to a spin rinse drying module 1414. The hand-off tool 1446 may transfer the substrate back to the transfer station 1450, and the hand-off tool 1440 may receive the substrate back to the cassette 1442 or cassette 1444. Hence, the sequence of operations may be characterized by the following: FOUP→treatment module→electroplating module (nanotwinned copper)→spin rinse drying module→FOUP.

In another example operation, the hand-off tool 1440 selects a substrate from cassette 1442 or cassette 1444. From a transfer station 1450, the hand-off tool 1446 gains access to the substrate and transfers the substrate to an electroplating module 1402. The electroplating module 1402 is configured electroplate non-nanotwinned copper on the substrate using copper electroplating solution. In some implementations, the electroplating module 1402 may be further configured to perform a surface post-treatment on the non-nanotwinned copper by exposing the non-nanotwinned copper to an oxidizing agent or other chemical reagent as described in the present disclosure. The hand-off tool 1446 may transfer the substrate from the electroplating module 1402 to an electroplating module 1404. The electroplating module 1404 may be configured to electroplate nanotwinned copper on the non-nanotwinned copper using a nanotwinned copper electroplating solution. In some implementations, the electroplating module 1404 may be configured to perform a surface pre-treatment on the non-nanotwinned copper by exposing the non-nanotwinned copper to an oxidizing agent or other chemical reagent as described in the present disclosure. Accordingly, surface treatment using the oxidizing agent or other chemical reagent may occur after plating non-nanotwinned copper in electroplating module 1402 or prior to plating nanotwinned copper in the electroplating module 1404. In some implementations, the hand-off tool 1446 may transfer the substrate from the electroplating module 1404 to a spin rinse drying module 1412. The hand-off tool 1446 may transfer the substrate back to the transfer station 1450, and the hand-off tool 1440 may receive the substrate back to the cassette 1442 or cassette 1444. Thus, the sequence of operations may be characterized by the following: FOUP→electroplating module (non-nanotwinned copper)→electroplating module (nanotwinned copper)→spin rinse drying module→FOUP.

In yet another example operation, the hand-off tool 1440 selects a substrate from cassette 1442 or cassette 1444. From a transfer station 1450, the hand-off tool 1446 gains access to the substrate and transfers the substrate to an electroplating module 1402. The electroplating module 1402 is configured electroplate non-nanotwinned copper on the substrate using copper electroplating solution. The hand-off tool 1446 may transfer the substrate from the electroplating module 1402 a spin rinse drying module 1414. The hand-off tool 1446 may transfer the substrate from the spin rinse drying module 1414 back to the transfer station 1450. From the transfer station 1450, the hand-off tool 1446 transfers the substrate to a treatment module 1412. The treatment module 1412 is configured to treat the non-nanotwinned copper with an oxidizing agent or other chemical reagent described in the present disclosure. The hand-off tool 1446 may transfer the substrate from the treatment module 1412 to an electroplating module 1404. The electroplating module 1404 may be configured to electroplate nanotwinned copper on the non-nanotwinned copper using a nanotwinned copper electroplating solution. In some implementations, the hand-off tool 1446 may transfer the substrate from the electroplating module 1404 to a spin rinse drying module 1412. The hand-off tool 1446 may transfer the substrate back to the transfer station 1450, and the hand-off tool 1440 may receive the substrate back to the cassette 1442 or cassette 1444. Therefore, the sequence of operations may be characterized by the following: FOUP→electroplating module (non-nanotwinned copper)→spin rinse drying module→FOUP→treatment module→electroplating module (nanotwinned copper)→spin rinse drying module→FOUP. In an alternative implementation, the spin rinse drying module can serve as a treatment module for exposing the non-nanotwinned copper to the oxidizing agent or other chemical reagent. Thus, the sequence of operations may be alternatively characterized by the following: FOUP→electroplating module (non-nanotwinned copper)→spin rinse drying module→electroplating module (nanotwinned copper)→spin rinse drying module→FOUP.

The foregoing examples demonstrate that the integrated system 1400 can perform two-step plating of non-nanotwinned copper and nanotwinned copper with surface pretreatment of non-nanotwinned copper without introducing a vacuum break in between operations.

In an example operation of the integrated system 1400, the hand-off tool 1440 selects a substrate from cassette 1442 or cassette 1444. From a transfer station 1450, the hand-off tool 1446 gains access to the substrate and transfers the substrate to an optional treatment module 1412. The treatment module 1412 is configured to treat a surface of the substrate with an oxidizing agent or other chemical reagent described in the present disclosure. The hand-off tool 1446 may transfer the substrate from the treatment module 1412 to an electroplating module 1402. The electroplating module 1402 may be configured to electroplate nanotwinned copper on the substrate using a nanotwinned copper electroplating solution. The hand-off tool 1446 may transfer the substrate from the electroplating module 1402 to an electroplating module 1404. The electroplating module 1404 may be configured to electroplate non-nanotwinned copper on the nanotwinned copper using a copper electroplating solution. In some implementations, the hand-off tool 1446 may transfer the substrate from the electroplating module 1404 to a removal module 1416 or spin rinse drying module 1414. The removal module 1416 or spin rinse drying module 1414 may be configured to remove excess non-nanotwinned copper that forms a copper overburden. The hand-off tool 1446 may transfer the substrate back to the transfer station 1450, and the hand-off tool 1440 may receive the substrate back to the cassette 1442 or cassette 1444. Hence, the sequence of operations may be characterized by the following: FOUP→treatment module→electroplating module (nanotwinned copper)→electroplating module (non-nanotwinned copper)→removal or spin rinse drying module→FOUP.

The foregoing example demonstrates that the integrated system 1400 can perform two-step plating of nanotwinned copper and non-nanotwinned copper without introducing a vacuum break in between operations.

An alternative implementation of an integrated apparatus 1500 is schematically illustrated in FIG. 15. In this embodiment, the apparatus 1500 has a set of electroplating cells 1507, each containing an electrolyte-containing bath, in a paired or multiple “duet” configuration. In addition to electroplating per se, the apparatus 1500 may perform a variety of other electroplating related processes and sub-steps, such as spin-rinsing, spin-drying, metal and silicon wet etching, electroless deposition, pre-wetting and pre-chemical treating, reducing, annealing, photoresist stripping, and surface pre-activation, for example. The apparatus 1500 is shown schematically looking top down in FIG. 15, and only a single level or “floor” is revealed in the figure, but it is to be readily understood by one having ordinary skill in the art that such an apparatus, e.g. the Sabre® 3D tool, can have two or more levels “stacked” on top of each other, each potentially having identical or different types of processing stations.

Referring once again to FIG. 15, the substrates 1506 that are to be electroplated are generally fed to the apparatus 1500 through a front end loading FOUP 1501 and, in this example, are brought from the FOUP to the main substrate processing area of the apparatus 1500 via a front-end robot 1502 that can retract and move a substrate 1506 driven by a spindle 1503 in multiple dimensions from one station to another of the accessible stations-two front-end accessible stations 1504 and also two front-end accessible stations 1508 are shown in this example. The front-end accessible stations 1504 and 1508 may include, for example, pre-treatment stations, and spin rinse drying (SRD) stations. Lateral movement from side-to-side of the front-end robot 1502 is accomplished utilizing robot track 1502a. Each of the substrates 1506 may be held by a cup/cone assembly (not shown) driven by a spindle 1503 connected to a motor (not shown), and the motor may be attached to a mounting bracket 1509. Also shown in this example are the four “duets” of electroplating cells 1507, for a total of eight cells 1507. The electroplating cells 1507 may be used for electroplating copper in recessed features. A system controller (not shown) may be coupled to the apparatus 1500 to control some or all of the properties of the apparatus 1500. The system controller may be programmed or otherwise configured to execute instructions according to processes described earlier herein.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., wafer, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing nanotwinned copper on a plated copper feature, the method comprising:
electroplating copper in a recessed feature of a substrate to form a plated copper feature;
exposing a surface of the plated copper feature to one or more oxidizing agents or other chemical reagents to treat the plated copper feature; and
electroplating nanotwinned copper on the plated copper feature.

2. The method of claim 1, wherein the nanotwinned copper comprises a nanotwinned region having (111)-oriented nanotwinned crystal copper grains.

3. The method of claim 1, wherein electroplating the nanotwinned copper comprises:
contacting the surface of the plated copper feature with a nanotwinned copper electroplating solution; and
applying a first current to the substrate when the plated copper feature is contacted with the nanotwinned copper electroplating solution to electroplate the nanotwinned copper having a plurality of nanotwins, wherein the first current comprises a pulsed current waveform that alternates between a constant current and no current.

4. The method of claim 1, wherein exposing the surface of the plated copper feature to the one or more oxidizing agents or other chemical reagents comprises:
exposing the surface of the plated copper feature to a wet treatment solution including an aqueous solution of a peroxide, sulfuric acid, dissolved ozone, or combinations thereof or a wet treatment solution including one or more electroplating leveling compounds.

5. The method of claim 1, wherein exposing the surface of the plated copper feature to the one or more oxidizing agents or other chemical reagents comprises:
exposing the surface of the plated copper feature to a dry treatment including an oxygen plasma or ozone.

6. An apparatus:
an electroplating chamber configured to hold a copper electroplating solution;
a nanotwinned copper electroplating chamber configured to hold a nanotwinned copper electroplating solution;
a power supply; and
a controller configured with program instructions for performing the following operations:
electroplating a copper feature on a substrate in the electroplating chamber;
exposing a surface of the copper feature to one or more oxidizing agents or other chemical reagents to treat the copper feature; and
electroplating nanotwinned copper on the copper feature in the nanotwinned copper electroplating chamber.

7. The apparatus of claim 6, wherein exposing the surface of the copper feature with the one or more oxidizing agents or other chemical reagents occurs as a post-treatment in the electroplating chamber or as a pre-treatment in the nanotwinned copper electroplating chamber.

8. The apparatus of claim 6, further comprising:
a treatment chamber configured to hold the one or more oxidizing agents or other chemical reagents, wherein exposing the surface of the copper feature with the one or more oxidizing agents or other chemical reagents occurs in the treatment chamber.

9. The apparatus of claim 6, wherein the one or more oxidizing agents or other chemical reagents include a wet treatment solution including an aqueous solution of a peroxide, sulfuric acid, dissolved ozone, or combinations thereof or a wet treatment solution including one or more electroplating leveling compounds.

10. A semiconductor device comprising:
a substrate;
a dielectric layer over the substrate;
an electrically conductive interconnect structure formed in the dielectric layer, wherein the electrically conductive interconnect structure includes a non-nanotwinned copper feature formed at least partially in the dielectric layer and a nanotwinned copper feature over the non-nanotwinned copper feature.

11. The semiconductor device of claim 10, wherein the non-nanotwinned copper partially or completely fills recesses in the dielectric layer, wherein the non-nanotwinned copper feature occupies a base of the electrically conductive interconnect structure and the nanotwinned copper feature occupies an upper portion of the electrically conductive interconnect structure.

12. A method of forming a nanotwinned copper via and one or more nanotwinned copper lines, the method comprising:
electroplating nanotwinned copper in a recessed region of a substrate and in regions outside the recessed region of the substrate; and
electroplating non-nanotwinned copper on the nanotwinned copper to at least fill the recessed region, wherein a filled recessed region defines a copper via, and wherein plated regions outside the recessed region define one or more copper lines.

13. The method of claim 12, wherein the regions outside the recessed region include a patterned photoresist layer, and wherein electroplating nanotwinned copper in the regions outside the recessed region include electroplating nanotwinned copper in regions defined by the patterned photoresist layer.

14. The method of claim 12, wherein electroplating non-nanotwinned copper on the nanotwinned copper includes electroplating non-nanotwinned copper in the regions outside the recessed region, wherein electroplated non-nanotwinned copper above a depth defined by a top surface of the nanotwinned copper in the regions outside of the recessed region define a copper overburden.

15. The method of claim 14, further comprising:
removing all or some of the copper overburden, wherein removing all or some of the copper overburden includes contacting the copper overburden with an etching solution comprising an oxidizing agent.

16. The method of claim 12, wherein electroplating nanotwinned copper comprises:
contacting a surface of the substrate with a nanotwinned copper electroplating solution; and
applying a first current to the substrate when the surface of the substrate is contacted with the nanotwinned copper electroplating solution to electroplate the nanotwinned copper having a plurality of nanotwins.

17. The method of claim 12, wherein electroplating non-nanotwinned copper comprises:
contacting an exposed surface of the nanotwinned copper with a copper electroplating solution, wherein the copper electroplating solution includes at least one or more accelerators; and
cathodically biasing the substrate to fill at least the recessed region with non-nanotwinned copper.

18. A semiconductor device comprising:
a substrate;
a dielectric layer over the substrate;
a copper via formed in the dielectric layer, wherein the copper via includes a non-nanotwinned copper layer formed over a nanotwinned copper layer; and
one or more copper redistribution layer (RDL) lines formed over the dielectric layer, wherein the one or more copper RDL lines are composed substantially of nanotwinned copper.

19. The semiconductor device of claim 18, wherein the non-nanotwinned copper layer fills recesses in the dielectric layer.

20. The semiconductor device of claim 18, wherein the nanotwinned copper layer has less film stress than the non-nanotwinned copper layer.
